(19) United States
(12) Patent Application Publication
(10) Pub. No.: US 2025/0218933 A1
(43) Pub. Date: Jul. 3, 2025

(54) DIELECTRIC WINDOWS FOR GROUPS OF VIAS THROUGH SEMICONDUCTOR SUBSTRATES

(71) Applicant: Micron Technology, Inc., Boise, ID (US)

(72) Inventors: Bharat Bhushan, Boise, ID (US); Kunal R. Parekh, Boise, ID (US); Brent Keeth, Boise, ID (US); Akshay N. Singh, Boise, ID (US)

(21) Appl. No.: 19/000,353

(22) Filed: Dec. 23, 2024

Related U.S. Application Data
(60) Provisional application No. 63/617,323, filed on Jan. 3, 2024.

(51) Int. Cl. H01L 23/522; H01L 21/768; H01L 23/00; H01L 23/528; H01L 23/532; H01L 25/18; H10B 80/00; H10D 80/20

(52) U.S. Cl. CPC H01L 23/5226; H01L 21/76804; H01L 21/76843; H01L 21/76877; H01L 23/5283; H01L 23/53295; H01L 24/03; H01L 24/05; H01L 24/08; H01L 24/80; H01L 25/18; H10B 80/00; H10D 80/20; H01L 2224/0383; H01L 2224/05578; H01L 2224/05647; H01L 2224/05686; H01L 2224/08145; H01L 2224/80895; H01L 2224/80896; H01L 2225/06544; H01L 2924/1431; H01L 2924/1436; H01L 2924/1438

(57) ABSTRACT

Methods, systems, and devices for dielectric windows for groups of vias through semiconductor substrates are described. For example, a semiconductor component (e.g., a semiconductor die, a semiconductor wafer) may be formed with one or more dielectric windows through a substrate of the semiconductor component, through which a group of multiple vias may be formed to support signaling with circuitry of the semiconductor component. In some implementations, a set of multiple cavities may be formed through a given dielectric portion and, in each of the multiple cavities, a conductive portion (e.g., one or more conductive materials) may be formed to support multiple electrically isolated contacts. In various examples, such vias may include contacts themselves (e.g., for vias that extend to the surface of the semiconductor component), or may be otherwise coupled with (e.g., contiguous with, electrically coupled with) a contact portion that has a different cross-section than the vias.

### CROSS REFERENCE

The present application for patent claims the benefit of U.S. Provisional Patent Application No. 63/617,323 by BHUSHAN et al., entitled “DIELECTRIC WINDOWS FOR GROUPS OF VIAS THROUGH SEMICONDUCTOR SUBSTRATES,” filed Jan. 3, 2024, which is assigned to the assignee hereof, and which is expressly incorporated by reference herein.

### TECHNICAL FIELD

The following relates to one or more semiconductor systems, including dielectric windows for groups of vias through semiconductor substrates.

### BACKGROUND

Memory devices are used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored by the memory cell. To store information, a memory device may write (e.g., program, set, assign) states to the memory cells. To access stored information, a memory device may read (e.g., sense, detect, retrieve, determine) states from the memory cells.

Some memory devices, among other devices (e.g., processing devices, semiconductor devices), may implement one or more semiconductor dies having electrical contacts for communicating signaling with circuitry of the one or more semiconductor dies. In some examples, performance characteristics of such devices may be related to a density of contacts that are implemented in at least some of the one or more semiconductor dies.

### BRIEF DESCRIPTION OF THE DRAWINGS

FIG. 1 shows an example of a system that supports dielectric windows for groups of vias through semiconductor substrates in accordance with examples as disclosed herein.

FIG. 2 shows an example of a system that supports dielectric windows for groups of vias through semiconductor substrates in accordance with examples as disclosed herein.

FIGS. 3A and 3B show examples of material layouts 300 and 350 that support vias through semiconductor substrates.

FIGS. 4 through 12 show examples of fabrication operations that support dielectric windows for groups of vias through semiconductor substrates in accordance with examples as disclosed herein.

FIG. 13 shows a flowchart illustrating a method or methods that support dielectric windows for groups of vias through semiconductor substrates in accordance with examples as disclosed herein.

### DETAILED DESCRIPTION

Some semiconductor systems (e.g., memory systems, processing systems) may implement a stack of semiconductor components (e.g., semiconductor dies), which may include one or more memory dies (e.g., array dies) or one or more stacks of memory dies that are stacked with a logic die that is operable to access a set of memory arrays distributed across the one or more memory dies. Such a stacked architecture may be implemented as part of a high bandwidth memory (HBM) system or a tightly-coupled dynamic random access memory (TCDRAM) system, among other examples, and may support solutions for memory-centric logic, such as graphics processing units (GPUs), among other implementations. In some examples, an HBM system may include one or more memory dies coupled (e.g., bonded, stacked) with a logic die. In some examples, a TCDRAM system may be closely coupled (e.g., physically coupled, electrically coupled, directly coupled, located at least in part in a common semiconductor die) with a processor, such as a GPU or other host device, as part of a physical memory map accessible to the processor. A logic die may include various components such as interface blocks (e.g., memory interface blocks, interface circuitry), logic blocks, controllers, processors, and other components. A semiconductor component (e.g., a semiconductor unit, a semiconductor subsystem), such as a logic die, may be formed as a single die with relevant circuitry, or may be formed with multiple die portions (e.g., relatively smaller dies, dies each including a respective subset of circuitry of a logic unit) that may be referred to as “chiplets” (e.g., logic chiplets), among other examples.

Semiconductor systems, such as HBM systems, TCDRAM systems, or other memory or processing systems may implement contacts (e.g., conductive contacts, communicative contacts) at a surface of a semiconductor die to be operable to convey information, power, or other signaling to or from the semiconductor die. Some implementations, including systems that implement a stacked semiconductor arrangement, may have performance characteristics that are associated with a relatively dense arrangement of such contacts. For example, a relatively dense arrangement of relatively small contacts in a semiconductor die may support relatively high throughput, relatively high-speed signaling, or relatively compact components, among other benefits. However, for such contacts that include or are otherwise supported by a conductive portion that passes through a semiconductor substrate (e.g., a through-substrate via, a through-silicon via (TSV)), contact density or signaling performance may be limited in arrangements that form each conductive portion in a respective (e.g., corresponding) cavity through the semiconductor substrate.

In accordance with examples as disclosed herein, a semiconductor component (e.g., a semiconductor die, a semiconductor wafer) may be formed with one or more dielectric portions (e.g., dielectric windows) through a substrate of the semiconductor component, through which a group of multiple vias may be formed to support signaling with circuitry of the semiconductor component. For example, for a given dielectric portion, a set of multiple cavities may be formed and, in each of the multiple cavities, a conductive portion (e.g., one or more conductive materials, conductive vias) may be formed to support multiple electrically isolated contacts. In some examples, such vias may include the contacts themselves (e.g., for vias that extend to a surface of the semiconductor component), or may be otherwise coupled with (e.g., contiguous with, electrically coupled with, coupled via a redistribution layer) a contact portion that has a different cross-section than the vias. By forming multiple vias through such a dielectric portion, a quantity of interfaces between different materials may be reduced, which may support a relatively higher density of contacts, or conductive portions with a relatively larger cross-sectional area, or both. Further, such techniques may reduce capacitance of or leakage associated with such vias by increasing a dielectric isolation between the conductor portions and the semiconductor substrate, which may support relatively higher signaling speed (e.g., higher clock speed), relatively lower power consumption, or both, among other benefits.

In addition to applicability in semiconductor systems as described herein, techniques for dielectric windows for groups of vias through semiconductor substrates may be generally implemented to improve the performance of various electronic devices and systems (including artificial intelligence (AI) applications, augmented reality (AR) applications, virtual reality (VR) applications, and/or gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of such electronic devices by supporting a relatively higher density of interconnections, interconnections with relatively larger cross sectional area (e.g., for reduced resistance, for improved material uniformity), or interconnections with relatively lower capacitance or leakage, any one or more of which may increase signaling throughput or increase signaling speed (e.g., improving memory access speeds), or reduce power consumption (e.g., improving battery life, improving efficiency), among other benefits.

Features of the disclosure are illustrated and described in the context of systems and architectures. Features of the disclosure are further illustrated and described in the context of material layouts, fabrication operations, and flowcharts.

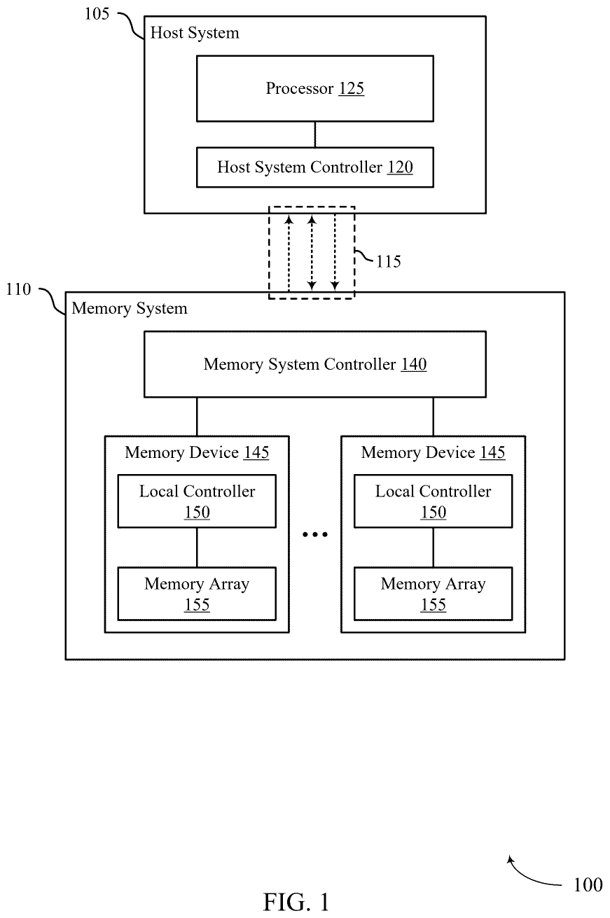

FIG. 1 shows an example of a system 100 that supports dielectric windows for groups of vias through semiconductor substrates in accordance with examples as disclosed herein. The system 100 may include portions of an electronic device, such as a computing device, a mobile computing device, a wireless communications device, a processing device, a vehicle, a smartphone, a wearable device, an internet-connected device, a vehicle controller, a system on a chip (SoC), or other stationary or portable electronic system, among other examples. The system 100 includes a host system 105, a memory system 110, and one or more channels 115 coupling the host system 105 with the memory system 110 (e.g., to support a communicative coupling). The system 100 may include any quantity of one or more memory systems 110 coupled with the host system 105.

The host system 105 may include one or more components (e.g., circuitry, processing circuitry, application processing circuitry, one or more processing components) that use memory to execute processes (e.g., applications, functions, computations), any one or more of which may be referred to as or be included in a processor 125. The processor 125 may include at least one of one or more processing elements that may be co-located or distributed, including a general-purpose processor, a digital signal processor (DSP), an application-specific integrated circuit (ASIC), a field-programmable gate array (FPGA) or other programmable logic device, a controller, discrete gate or transistor logic, one or more discrete hardware components, or a combination thereof. The processor 125 may be an example of a central processing unit (CPU), a graphics processing unit (GPU), a general-purpose GPU (GPGPU), or an SoC or a component thereof, among other examples.

In some examples, the system 100 or the host system 105 may include an input component, an output component, or a combination thereof. Input components may include a sensor, a microphone, a keyboard, another processor (e.g., on a printed circuit board), an interface (e.g., a user interface, an interface between other devices), or a peripheral that interfaces with system 100 via one or more peripheral components, among other examples. Output components may include a display, audio speakers, a printing device, another processor (e.g., on a printed circuit board), or a peripheral that interfaces with the system 100 via one or more peripheral components, among other examples.

The host system 105 may also include at least one of one or more components (e.g., circuitry, logic, instructions) that implement the functions of an external memory controller (e.g., a host system memory controller), which may be referred to as or be included in a host system controller 120. For example, a host system controller 120 may issue commands or other signaling for operating the memory system 110, such as write commands, read commands, configuration signaling or other operational signaling. In some examples, the host system controller 120, or associated functions described herein, may be implemented by or be part of the processor 125. For example, a host system controller 120 may be hardware, instructions (e.g., software, firmware), or a combination thereof implemented by the processor 125 or other component of the host system 105. In various examples, a host system 105 or a host system controller 120 may be referred to as a host.

The memory system 110 provides physical memory locations (e.g., addresses) that may be used or referenced by the system 100. The memory system 110 may include a memory system controller 140 and one or more memory devices 145 (e.g., memory packages, memory dies, memory units) operable to store data. The memory system 110 may be configurable for operations with different types of host systems 105, and may respond to commands from the host system 105 (e.g., from a host system controller 120). For example, the memory system 110 (e.g., a memory system controller 140) may receive a write command indicating that the memory system 110 is to store data received from the host system 105, or receive a read command indicating that the memory system 110 is to provide data stored in a memory device 145 to the host system 105, or receive a refresh command indicating that the memory system 110 is to refresh data stored in a memory device 145, among other types of commands and responsive operations.

A memory system controller 140 may include at least one of one or more components (e.g., circuitry, logic, instructions) operable to control operations of the memory system 110. A memory system controller 140 may include hardware or instructions that support the memory system 110 performing various operations, and may be operable to receive, transmit, or respond to commands, data, or control information related to operations of the memory system 110. A memory system controller 140 may be operable to communicate with one or more of a host system controller 120, one or more memory devices 145, or a processor 125. In some examples, a memory system controller 140 may control operations of the memory system 110 in cooperation with the host system controller 120, a local controller 150 of a memory device 145, or any combination thereof. Although the example of memory system controller 140 is illustrated as a separate component of the memory system 110, in some examples, aspects of the functionality of the memory system 110 may be implemented by a processor 125, a host system controller 120, at least one of one or more local controllers 150, or any combination thereof.

Each memory device 145 may include a local controller 150 and one or more memory arrays 155. A memory array 155 may be a collection of memory cells (e.g., a two-dimensional array, a three-dimensional array), with each memory cell being operable to store data (e.g., as one or more stored bits). Each memory array 155 may include memory cells of various architectures, such as random access memory (RAM) cells, dynamic RAM (DRAM) cells, synchronous dynamic RAM (SDRAM) cells, static RAM (SRAM) cells, ferroelectric RAM (FeRAM) cells, magnetic RAM (MRAM) cells, resistive RAM (RRAM) cells, phase change memory (PCM) cells, chalcogenide memory cells, not-or (NOR) memory cells, and not-and (NAND) memory cells, or any combination thereof.

A local controller 150 (e.g., a logic controller, an interface controller, one or more processors) may include at least one of one or more components (e.g., circuitry, logic, instructions) operable to control operations of a memory device 145. In some examples, a local controller 150 may be operable to communicate (e.g., receive or transmit data or commands or both) with a memory system controller 140. In some examples, a memory system 110 may not include a memory system controller 140, and a local controller 150 or a host system controller 120 may perform functions of a memory system controller 140 described herein. In some examples, a local controller 150, or a memory system controller 140, or both may include decoding components operable for accessing addresses of a memory array 155, sense components for sensing states of memory cells of a memory array 155, write components for writing states to memory cells of a memory array 155, or various other components operable for supporting described operations of a memory system 110.

In some examples, at least one of the memory arrays 155 of a memory device 145 may be formed using one or more semiconductor components (e.g., one or more memory dies). In some examples, a memory array 155 may be formed using multiple semiconductor components that are stacked relative to one another (e.g., as stacked semiconductor dies). In some examples, such a stack of semiconductor components that includes one or more memory arrays 155 may be stacked over another semiconductor component that includes at least a portion of a local controller 150. In some implementations, a stack of multiple semiconductor components including one or more memory arrays 155 and at least a portion of a local controller 150 may form at least a portion of an HBM device. In some implementations, a stack of multiple semiconductor components including one or more memory arrays 155 and at least a portion of a local controller 150 may form at least a portion of a TCDRAM device.

In some examples, a quantity of memory dies in a stack of memory dies may increase as the size and density of one or more memory arrays 155 increases. In some examples, the quantity of memory dies in a stack of memory dies may be at least 8,12,16, or more. A routing of signals (e.g., input signals, output signals) between such memory dies and a controller (e.g., a local controller 150) may be achieved through vias that extend through a substrate of the dies, such as TSVs. A higher quantity of TSVs may be implemented to communicate signals through a stack as a quantity of memory dies increases. In some examples, with a limited surface area of a memory die (e.g., for coupling dies in a stack), increasing a quantity of TSVs may involve reducing a pitch of the TSVs. In one exemplary aspect, the TSV pitch may be less than 1.6 μm. In another exemplary aspect, the TSV pitch may be 1.25 μm or less.

A host system 105 (e.g., a host system controller 120) and a memory system 110 (e.g., a memory system controller 140) may communicate information (e.g., data, commands, control information, configuration information) using one or more channels 115. Each channel 115 may be an example of a transmission medium that carries information, and each channel 115 may include one or more signal paths (e.g., a transmission medium, an electrical conductor, a conductive path) between terminals (e.g., nodes, pins, contacts) associated with the components of the system 100. A terminal may be an example of a conductive input or output point of a device of the system 100, and a terminal may be operable as part of a channel 115. In some implementations, at least the channels 115 between a host system 105 and a memory system 110 may include or be referred to as a host interface (e.g., a physical host interface). To support communications over channels 115, a host system 105 (e.g., a host system controller 120) and a memory system 110 (e.g., a memory system controller 140) may include receivers (e.g., latches) for receiving signals, transmitters (e.g., drivers) for transmitting signals, decoders for decoding or demodulating received signals, or encoders for encoding or modulating signals to be transmitted, among other components that support signaling over channels 115, which may be included in a respective interface portion of the respective system.

A channel 115 be dedicated to communicating one or more types of information, and channels 115 may include unidirectional channels, bidirectional channels, or both. For example, the channels 115 may include one or more command/address channels, one or more clock signal channels, one or more data channels, among other channels or combinations thereof. In some examples, a channel 115 may be configured to provide power from one system to another (e.g., from the host system 105 to the memory system 110, in accordance with a regulated voltage). In some examples, at least a subset of channels 115 may be configured in accordance with a protocol (e.g., a logical protocol, a communications protocol, an operational protocol, an industry standard), which may support configured operations of and interactions between a host system 105 and a memory system 110.

In some examples, at least a portion of the system 100 may implement a stacked architecture in which multiple semiconductor components (e.g., semiconductor dies) are physically and communicatively coupled. In some such implementations, circuitry for accessing one or more memory arrays 155 (e.g., circuitry of a memory system 110) may be distributed among multiple semiconductor dies of a stack (e.g., a stack of multiple directly-coupled semiconductor dies). For example, a first die may include a set of multiple first interface blocks (e.g., memory interface blocks, instances of first interface circuitry) and one or more second dies may include corresponding second interface blocks, each coupled with a first interface block of the first die, which are each configured to access one or more memory arrays 155 of the second dies. In some examples, the system may include a controller (e.g., a memory controller, an interface controller, a host interface controller, at least a portion of a memory system controller 140) for each set of one or more first interface blocks to support access operations (e.g., to access one or more memory arrays 155) via the set of first interface blocks. In some examples, such a controller may be located in the same first die as the first interface blocks. In some examples, multiple semiconductor dies of a memory system 110 or of a system 100 (e.g., an HBM system including aspects of a memory system 110, a TCDRAM system including aspects of a memory system 110 and a host system 105) may include one or more array dies stacked with a logic die (e.g., that includes aspects of the host system 105, that is coupled with another die that includes the host system 105) that includes interface blocks operable to access a set of memory arrays 155 distributed across the one or more second dies.

In accordance with examples as disclosed herein, a semiconductor component (e.g., a semiconductor die including at least a portion of a system 100, such as a semiconductor die including at least a portion of a host system 105, or at least a portion of a memory system 110, or a combination thereof) may be formed with one or more dielectric portions through a substrate of the semiconductor component, through which a group of multiple vias may be formed to support signaling with circuitry of the semiconductor component. For example, for a given dielectric portion, a set of multiple cavities may be formed and, in each of the multiple cavities, a conductive portion may be formed to support multiple electrically isolated contacts. Such techniques may be implemented to support a relatively higher density of interconnections, interconnections with relatively larger cross sectional area, or interconnections with relatively lower capacitance or leakage, any one or more of which may increase signaling throughput or increase signaling speed (e.g., improving memory access speeds), or reduce power consumption (e.g., improving battery life, improving efficiency), among other benefits to performance of a host system 105, of a memory system 110, or a system 100 that implements semiconductor component contacts.

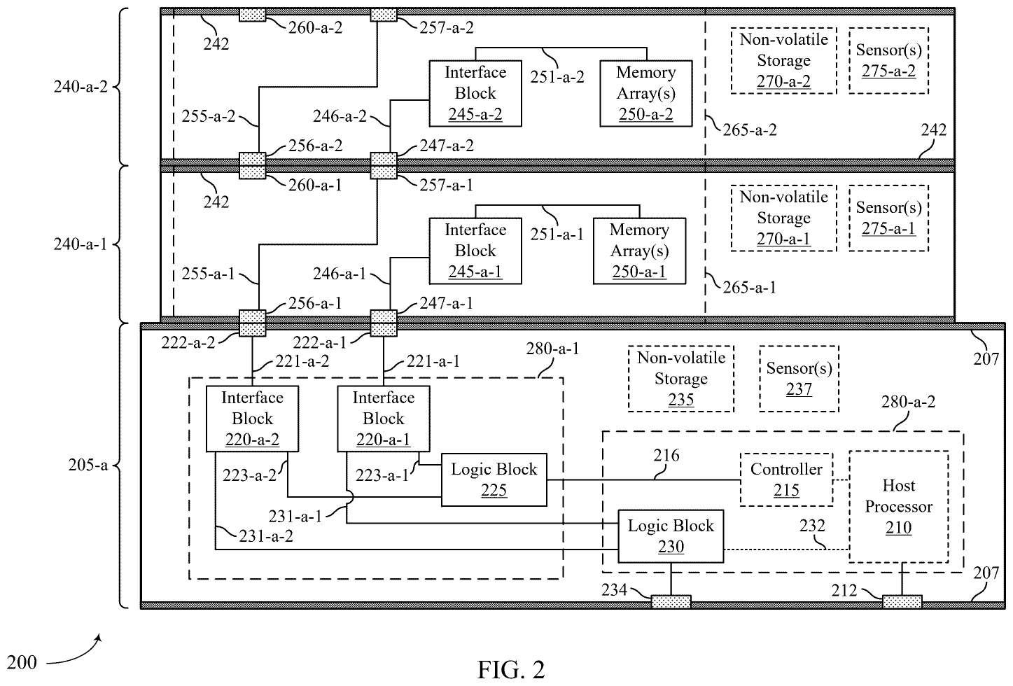

FIG. 2 shows an example of a system 200 (e.g., a semiconductor system, a system of coupled semiconductor dies, an HBM system, a TCDRAM system) that supports dielectric windows for groups of vias through semiconductor substrates in accordance with examples as disclosed herein. The system 200 illustrates an example of a die 205 (e.g., a die 205-a, a semiconductor die, a logic die, a processor die, a host die, a logic unit) that is coupled with one or more dies 240 (e.g., dies 240-a-1 and 240-a-2, semiconductor dies, memory dies, array dies, memory units). A die 205 or a die 240 may be formed using a respective semiconductor substrate (e.g., a substrate of crystalline semiconductor material such as silicon, germanium, silicon-germanium, gallium arsenide, or gallium nitride), or a silicon-on-insulator (SOI) substrate (e.g., silicon-on-glass (SOG), silicon-on-sapphire (SOS)), or epitaxial semiconductor materials formed on another substrate, among other examples. Although the illustrated example of a system 200 includes two dies 240, a system 200 in accordance with the described techniques may include any quantity of one or more dies 240 coupled with a die 205, among other dies of a stack or other coupled layout. For example, such a system 200 may include 8, 12, 16, or more dies 240. Further, although non-limiting examples of the system 200 herein are generally described in terms of applicability to memory systems, memory sub-systems, memory devices, or a combination thereof, examples of the system 200 are not so limited. For example, aspects of the present disclosure may be applied as well to any computing system, computing sub-system, processing system, processing sub-system, component, device, structure, or other types of systems or sub-systems used for applications such as data collecting, data processing, data storage, networking, communication, power, artificial intelligence, system-on-a-chip, control, telemetry, sensing and monitoring, digital entertainment, or any combination thereof.

The system 200 illustrates an example of interface circuitry between a host and memory (e.g., via a host interface, via a physical host interface) that is implemented in (e.g., divided between) multiple semiconductor dies (e.g., a stack of directly-coupled dies). For example, the die 205-a may include a set of one or more interface blocks 220 (e.g., interface blocks 220-a-1 and 220-a-2, memory interface blocks), and each die 240 may include a set of one or more interface blocks 245 (e.g., access interface blocks) and one or more memory arrays 250 (e.g., die 240-a-1 including an interface block 245-a-1 coupled with a set of one or more memory arrays 250-a-1, die 240-a-2 including an interface block 245-a-2 coupled with a set of one or more memory arrays 250-a-2). The memory arrays 250 may be examples of memory arrays 155, or a portion thereof, and may include memory cells of various architectures, such as RAM, DRAM, SDRAM, SRAM, FeRAM, MRAM, RRAM, PCM, chalcogenide, NOR, or NAND memory cells, or any combination thereof.

Although the example of system 200 is illustrated with one interface block 245 included in each die 240, a die 240 in accordance with the described techniques may include any quantity of one or more interface blocks 245, each coupled with a respective set of one or more memory arrays 250, and each coupled with an interface block 220 of a die 205. Thus, the interface circuitry of a system 200 may include one or more interface blocks 220 of a die 205, with each interface block 220 being coupled with (e.g., in communication with) one or more interfaces block 245 of a die 240 (e.g., external to the die 205). In some examples, a coupled combination of an interface block 220 and an interface block 245 (e.g., coupled via a bus associated with one or more channels, such as one or more data channels, one or more control channels, one or more clock channels, one or more pseudo-channels, or a combination thereof) may include or be referred to as a data path associated with a respective set of one or more memory arrays 250. In some examples, respective signals may be routed between a die 205 and dies 240. For example, as shown in the system 200, signaling may be directly routed between the interface block 245-a-1 and the interface block 220-a-1 (e.g., through a bus 246-a-1 of the die 240-a-1 and a bus 221-a-1 of the die 205-a). Similarly, signaling may be directly routed between the interface block 245-a-2 and the interface block 220-a-2 (e.g., through a bus 246-a-2 of the die 240-a-2, a bus 255-a-1 of the die 240-a-1, and a bus 221-a-2 of the die 205-a). In various examples, buses 246, 255, and 221, among other interconnections of the system 200, may include a portion of one or more RDLs, or one or more TSVs, among other signal path conductor implementations.

In some implementations (e.g., TCDRAM implementations), a die 205 may include a host processor 210. A host processor 210 may be an example of a host system 105, or a portion thereof (e.g., a processor 125, aspects of a host system controller 120, or both). The host processor 210 may be configured to perform operations that implement storage of the memory arrays 250 (e.g., to support an application or other function of a host system 105, which may request access of the memory arrays 250). For example, the host processor 210 may receive data read from the memory arrays 250, or may transmit data to be written to the memory arrays 250, or both (e.g., in accordance with an application or other operations of the host processor 210). Additionally, or alternatively, a host processor 210 may be external to a die 205 (e.g., in HBM implementations), such as in another semiconductor die or other component that is coupled with (e.g., communicatively coupled with, directly coupled with, bonded with, coupled via another intervening component) the die 205 via one or more contacts 212 (e.g., externally-accessible terminals of the die 205).

A host processor 210 may be configured to communicate (e.g., transmit, receive) signaling with interface blocks 220 via a host interface 216 (e.g., a physical host interface), which may implement aspects of channels 115. In some examples, a host interface 216 may provide a communicative coupling between physical or functional boundaries of a host system 105 and a memory system 110. For example, the host processor 210 may be configured to communicate access signaling (e.g., control signaling, access command signaling, data signaling, configuration signaling) via a host interface 216 to support access operations (e.g., read operations, write operations) on the memory arrays 250, among other operations. Although the example of system 200 includes a single host interface 216, a system in accordance with the described techniques may include any quantity of one or more host interfaces 216 for accessing memory arrays 250 of the system.

In some examples, a respective host interface 216 may be coupled between a set of one or more interface blocks 220 (e.g., interface blocks 220-a-1 and 220-a-2) and a respective controller 215. A controller 215 may be an example of control circuitry (e.g., memory controller circuitry, host interface control circuitry) associated with a host system 105, and may be associated with implementing respective instances of one or more aspects of a host system controller 120, or of a memory system controller 140, or a combination thereof. For example, a controller 215 may be operable to respond to indications (e.g., requests, commands) from the host processor 210 to access one or more memory arrays 250 in support of a function or application of the host processor 210, to transmit associated commands (e.g., for one or more interface blocks 220) to access the one or more memory arrays 250, and to communicate data (e.g., write data, read data) with the host processor 210, among other functions.

In some examples, one or more controllers 215 may be implemented in a die 205 (e.g., the same die that includes one or more interface blocks 220) whether a host processor 210 is included in the die 205, or is external to the die 205. In some other examples, controllers 215 or associated circuitry or functionality may be implemented external to a die 205 (e.g., in another die, not shown, coupled with respective interface blocks 220 via respective terminals for each of the respective host interfaces 216), which may be in the same die as or a different die from a die that includes a host processor 210. An interface block 220 may be operable via a single controller 215, or by one or more of a set of multiple controllers 215 (e.g., in accordance with a controller multiplexing scheme). In some other examples, aspects of one or more controllers 215 may be included in the host processor 210 (e.g., as a memory interface of the host processor 210, as a memory interface of a host system 105).

Although, in some examples, a controller 215 may be directly coupled with one or more interface blocks 220 (not shown), in some other examples, a controller 215 (e.g., a host interface 216) may be coupled with a set of multiple interface blocks 220 via a logic block 225 (e.g., logic circuitry for a channel set, logic circuitry for a host interface 216, multiplexing circuitry). For example, the logic block 225 may be coupled with the interface block 220-a-1 via a bus 223-a-1 and coupled with the interface block 220-a-2 via a bus 223-a-2. A controller 215 and one or more corresponding interface blocks 220 and may communicate (e.g., collaborate) using the host interface 216 via a logic block 225 to perform one or more operations (e.g., scheduling operations, access operations, operations initiated by a host processor 210) associated with accessing a corresponding set of one or more memory arrays 250.

In some examples, a logic block 225, a controller 215, or a host interface 216, or a combination thereof may be associated with a “channel set” that corresponds to multiple memory arrays 250 (e.g., for parallel or otherwise coordinated access of the multiple memory arrays 250). For example, such a channel set may be associated with multiple memory arrays 250 accessed via a single interface block 245, or multiple memory arrays 250 each accessed via a respective one of the interface blocks 245, or multiple memory arrays 250 each accessed via a respective one of the interface blocks 220, any of which may be associated with signaling via a single logic block 225, via a single host interface 216, or via a single controller 215. These and other configurations for implementing one or more channel sets in a system may support various techniques for parallelism and high bandwidth data transfer, memory management operations, repair and replacement techniques, or power and thermal distribution, among other techniques that leverage the described coupling of components and interfaces among multiple semiconductor dies (e.g., in accordance with a high bandwidth memory configuration of the system 200, in accordance with a tightly-coupled configuration of the system 200). In some examples, such techniques may be implemented (e.g., at or using a logic block 225) in a manner that is transparent to the host interface 216 or other aspects of a host system 105.

In some examples, a host interface 216 may include a respective set of one or more signal paths for each logic block 225 or interface block 220, such that the host processor 210 may communicate with each logic block 225 or interface block 220 via its corresponding set of signal paths (e.g., in accordance with a selection of the corresponding set to perform access operations via a logic block 225 or interface block 220 that is selected by the host processor 210). Additionally, or alternatively, a host interface 216 may include one or more signal paths that are shared among multiple logic blocks 225 (not shown) or interface blocks 220, and a logic block 225, an interface block 220, or a host processor 210, or any of these may interpret, ignore, respond to, or inhibit response to signaling via shared signal paths of the host interface 216 based on a logical indication (e.g., an addressing indication associated with the logic block 225 or interface block 220, an interface enable signal, or an interface select signal, which may be provided by the host processor 210, the corresponding logic block 225, or the corresponding interface block 220 depending on signaling direction).

In some examples, a host processor 210 may determine to access an address (e.g., a logical address of a memory array 250, a physical address of a memory array 250, an address of a logic block 225, an address of an interface block 220, an address of a host interface 216, in response to an application of or supported by the host processor 210), and determine which controller 215 to transmit access signaling to for accessing the address (e.g., a controller 215, logic block 225, or interface block 220 corresponding to the address). In some examples, the address may be associated with a row of memory cells of the memory array 250, a column of memory cells of the memory array 250, or both. The host processor 210 may transmit access signaling (e.g., one or more access signals, one or more access commands) to the determined controller 215 and, in turn, the determined controller 215 may transmit access signaling to the corresponding logic block 225 or interface block 220. The corresponding interface block 220 may subsequently transmit access signaling to the coupled interface block 245 to access the determined address (e.g., of a corresponding memory array 250).

A die 205 may also include a logic block 230 (e.g., a shared logic block, a central logic block, common logic circuitry, evaluation circuitry, memory system configuration circuitry, memory system management circuitry), which may be configured to communicate (e.g., transmit, receive) signaling with the logic blocks 225, the interface blocks 220, or both of the die 205. In some cases, a logic block 230 may be configured to communicate information (e.g., commands, instructions, indications, data) with one or more logic blocks 225 or interface blocks 220 to facilitate operations of the system 200. For example, a logic block 230 may be configured to transmit configuration signaling (e.g., initialization signaling, evaluation signaling, mapping signaling), which may be received by logic blocks 225 or interface blocks 220 to support configuration of the logic blocks 225 or interface blocks 220, or other aspects of operating the dies 240 (e.g., via the respective interface blocks 245). A logic block 230 may be coupled with each logic block 225 and each interface block 220 via a respective bus 231. In some examples, such buses may each include a respective set of one or more signal paths, such that a logic block 230 may communicate with each logic block 225 or each interface block 220 via the respective set of signal paths. Additionally, or alternatively, such buses may include one or more signal paths that are shared among multiple logic blocks 225 or interface blocks 220 (not shown).

In some implementations, a logic block 230 may be configured to communicate (e.g., transmit, receive) signaling with a host processor 210 (e.g., via a bus 232, via a contact 212 for a host processor 210 external to a die 205) such that the logic block 230 may support an interface between the host processor 210 and the logic blocks 225 or interface blocks 220. For example, a host processor 210 may be configured to transmit initialization signaling (e.g., boot commands), or other configuration or operational signaling, which may be received by a logic block 230 to support initialization, configuration, evaluation, or other operations of the logic blocks 225 or interface blocks 220. Additionally, or alternatively, in some implementations, a logic block 230 may be configured to communicate (e.g., transmit, receive) signaling with a component outside the system 200 (e.g., via a contact 234, which may be an externally-accessible terminal of the die 205), such that the logic block 230 may support an interface that bypasses a host processor 210. Additionally, or alternatively, a logic block 230 may communicate with a host processor 210, and may communicate with one or more memory arrays 250 of one or more dies 240 (e.g., to perform self-test operations for access of memory arrays 250). In some examples, such implementations may support evaluations, configurations, or other operations of the system 200, via one or more contacts 234 that are accessible at a physical interface of the system, during manufacturing, assembly, validation, or other operation associated with the system 200 (e.g., before coupling with a host processor 210, without implementing a host processor 210, for operations independent of a host processor). Additionally, or alternatively, a logic block 230 may implement one or more aspects of a controller 215. For example, a logic block 230 may include or operate as one or more controllers 215 and may perform operations ascribed to a controller 215.

Each interface block 220 may be coupled with at least a respective bus 221 of the die 205, and a respective bus 246 of a die 240, that are configured to communicate signaling with a corresponding interface block 245 (e.g., via one or more associated signal paths). For example, the interface block 220-a-1 may be coupled with the interface block 245-a-1 via a bus 221-a-1 and a bus 246-a-1, and the interface block 220-a-2 may be coupled with the interface block 245-a-2 via a bus 221-a-2 and a bus 246-a-2. In some examples, a die 240 may include a bus that bypasses operational circuitry of the die 240 (e.g., that bypasses interface blocks 245 of a given die 240), such as a bus 255. For example, the interface block 220-a-2 may be coupled with the interface block 245-a-2 of the die 240-a-2 via a bus 255-a-1 of the die 240-a-1, which may bypass interface blocks 245 of the die 240-a-1. Such techniques may be extended for interconnection among more than two dies 240 (e.g., for interconnection via a respective bus 255 of multiple dies 240).

The respective signal paths of buses 221, 246, and 255 may be coupled with one another, from one die to another, via various arrangements of contacts at the surfaces of interfacing dies (e.g., exposed contacts, metal surfaces of the respective dies). For example, the bus 221-a-1 may be coupled with the bus 246-a-1 via a contact 222-a-1 of (e.g., at a surface of) the die 205-a and a contact 247-a-1 of the die 240-a-1, the bus 221-a-2 may be coupled with the bus 255-a-1 via a contact 222-a-2 of the die 205 and a contact 256-a-1 of the die 240-a-1, the bus 255-a-1 may be coupled with the bus 246-a-2 via a contact 257-a-1 of the die 240-a-1 and a contact 247-a-2 of the die 240-a-2, and so on. Although each respective bus is illustrated with a single line, coupled via singular contacts, it is to be understood that each signal path of a given bus may be associated with respective contacts to support a separate communicative coupling via each signal path of the given bus. In some examples, a bus 255 may traverse a portion of a die 240 (e.g., in an in-plane direction, along a direction different from a thickness direction, in a waterfall arrangement, in a staircase arrangement), which may support an arrangement of contacts 222 along a surface of a die 205, among other contacts, being coupled with interface blocks 245 of different dies 240 along a stack direction (e.g., via respective contacts 256 and 257 that are non-overlapping when viewed along a thickness direction).

The interconnection of interfacing contacts may be supported by various techniques. For example, in a hybrid bonding implementation, interfacing contacts may be coupled by a fusion of conductive materials (e.g., electrically conductive materials) of the interfacing contacts (e.g., without solder or other intervening material between contacts). For example, in an assembled condition, the coupling of the die 205-a with the die 240-a-1 may include a conductive material of the contact 222-a-2 being fused with a conductive material of the contact 256-a-1, and the coupling of the die 240-a-1 with the die 240-a-2 may include a conductive material of the contact 257-a-1 being fused with a conductive material of the contact 247-a-2, and so on. In some examples, such coupling may include an inoperative fusion of contacts (e.g., a non-communicative coupling, a physical coupling), such as a fusion of the contact 260-a-1 with the contact 256-a-2, neither of which are coupled with operative circuitry of the dies 240-a-1 or 240-a-2. In some examples, such techniques may be implemented to improve coupling strength or uniformity (e.g., implementing contacts 260, which may not be operatively coupled with an interface block 245 or an interface block 220), or such a coupling may be a byproduct of a repetition of components that, in various configurations, may be operative or inoperative. (e.g., where, for dies 240 with a common arrangement of contacts 256 and 257, contacts 256-a-1 and 257-a-1 provide a communicative path between the interface block 245-a-2 and the interface block 220-a-2, but the contacts 256-a-2 and 257-a-2 do not provide a communicative path between an interface block 245 and an interface block 220).

In some examples, a fusion of conductive materials between dies (e.g., between contacts) may be accompanied by a fusion of other materials at one or more surfaces of the interfacing dies. For example, in an assembled condition, the coupling of the die 205 with the die 240-a-1 may include a dielectric material 207 (e.g., an electrically non-conductive material) of the die 205-a being fused with a dielectric material 242 of the die 240-a-1, and the coupling of the die 240-a-1 with the die 240-a-2 may include a dielectric material 242 of the die 240-a-1 being fused with a dielectric material 242 of the die 240-a-2. In some examples, such dielectric materials may include an oxide, a nitride, a carbide, an oxide-nitride, an oxide-carbide, or other conversion or doping of a substrate material (e.g., a semiconductor substrate material) or other material of the die 205 or dies 240, among other materials that may support such fusion. However, coupling among dies 205 and dies 240 may be implemented in accordance with other techniques, which may implement solder, adhesives, thermal interface materials, and other intervening materials or combinations of materials.

In some examples, dies 240 may be coupled in a stack (e.g., forming a “cube” or other arrangement of dies 240), and one or more of such stacks may subsequently be coupled with a die 205 (e.g., in a stack-to-chip bonding arrangement). In some examples, respective set(s) of one or more dies 240 may be coupled with each die 205 of multiple dies 205 as formed in a wafer (e.g., in a chip-to-wafer bonding arrangement, in a stack-to-wafer bonding arrangement, before cutting the wafer of dies 205), and the dies 205 of the wafer, each coupled with their respective set(s) of dies 240, may be separated from one another (e.g., by cutting at least the wafer of dies 205, by singulation). In some other examples, respective set(s) of one or more dies 240 may be coupled with a respective die 205 after the die 205 is separated from a wafer of dies 205 (e.g., in a chip-to-chip bonding arrangement). In some other examples, a respective set of one or more wafers, each including multiple dies 240, may be coupled in a stack (e.g., in a wafer-to-wafer bonding arrangement). In various examples, such techniques may be followed by separating stacks of dies 240 from the coupled wafers, or the stack of wafers having dies 240 may be coupled with another wafer including multiple dies 205 (e.g., in a second wafer-to-wafer bonding arrangement), which may be followed by separating systems 200 from the coupled wafers. In some other examples, wafer-to-wafer coupling techniques may be implemented by stacking one or more wafers of dies 240 (e.g., sequentially) over a wafer of dies 205 before separation into systems 200, among other examples for forming systems 200.

The buses 221, 246, and 255 may be implemented to provide a configured signaling (e.g., a coordinated signaling, a logical signaling, modulated signaling, digital signaling) between an interface block 220 and a corresponding interface block 245, which may involve various modulation or encoding techniques by a transmitting interface block (e.g., via a driver component of the transmitting interface block). In some examples, such signaling may be supported by (e.g., accompanied by) clock signaling communicated via the respective buses (e.g., in coordination with signal transmission). For example, the buses may be configured to convey one or more clock signals transmitted by the interface block 220 for reception by the interface block 245 (e.g., to trigger signal reception by a latch or other reception component of the interface block 245, to support clocked operations of the interface block 245). Additionally, or alternatively, the buses may be configured to convey one or more clock signals transmitted by the interface block 245 for reception by the interface block 220 (e.g., to trigger signal reception by a latch or other reception component of the interface block 220, to support clocked operations of the interface block 220). Such clock signals may be associated with the communication (e.g., unidirectional communication, bidirectional communication, deterministic communication) of various signaling, such as control signaling, command signaling, data signaling, or any combination thereof. For example, the buses may include one or more signal paths for communications of a data bus (e.g., one or more data channels, a DQ bus, via a data interface of the interface blocks) in accordance with one or more corresponding clock signals (e.g., data clock signals), or one or more signal paths for communications of a control bus (e.g., a command/address (C/A) bus, via a command interface of the interface blocks) in accordance with one or more clock signals (e.g., control clock signals), or any combination thereof.

Interface blocks 220, interface blocks 245, logic blocks 225, and a logic block 230 each may include circuitry (signaling circuitry, multiplexing circuitry, processing circuitry, controller circuitry, logic circuitry, physical components, hardware) in various configurations (e.g., hardware configurations, logic configurations, software or instruction configurations) that support the functionality allocated to the respective block for accessing or otherwise operating a corresponding set of memory arrays 250. For example, interface blocks 220 may include circuitry configured to perform a first subset of operations that support access of the memory arrays 250, and interface blocks 245 may include circuitry configured to perform a second subset of operations that support access of the memory arrays 250. In some examples, the interface blocks 220, the interface blocks 245, and logic blocks 225 may support a functional split or distribution of functionality associated with a memory system controller 140, a local controller 150, or both across multiple dies (e.g., a die 205 and at least one die 240). In some implementations, a logic block 230 may be configured to coordinate or configure aspects of the operations of the interface blocks 220, of the interface blocks 245, of the logic blocks 225, or a combination thereof, and may support implementing one or more aspects of a memory system controller 140. Such operations, or subsets of operations, may include operations performed in response to commands from the host processor 210 or a controller 215, or operations performed without commands from a host processor 210 or a controller 215 (e.g., operations determined by or initiated by a logic block 225, operations determined by or initiated by an interface block 220, operations determined by or initiated by an interface block 245, operations determined by or initiated by a logic block 230), or various combinations thereof.

In some implementations, the system 200 may include one or more instances of non-volatile storage (e.g., non-volatile storage 235 of a die 205, non-volatile storage 270 of one or more dies 240, or a combination thereof). In some examples, a logic block 230, logic blocks 225, interface blocks 220, interface blocks 245, or a combination thereof may be configured to communicate signaling with one or more instances of non-volatile storage. For example, a logic block 230, logic blocks 225, interface blocks 220, or interface blocks 245 may be coupled with one or more instances of non-volatile storage via one or more buses (not shown), or respective contacts (not shown), where applicable, which may each include one or more signal paths operable to communicate signaling (e.g., command signaling, data signaling). In some examples, a logic block 230, one or more logic blocks 225, one or more interface blocks 220, one or more interface blocks 245, or a combination thereof may configure one or more operations based on information (e.g., instructions, configurations, parameters) stored in one or more instances of non-volatile storage. Additionally, or alternatively, in some examples, a logic block 230, one or more logic blocks 225, one or more interface blocks 220, one or more interface blocks 245, or a combination thereof may write information (e.g., configuration information, evaluation information) to be stored in one or more instances of non-volatile storage. In some examples, such non-volatile storage may include fuses, antifuses, or other types of one-time programmable storage elements, or any combination thereof.

In some implementations, the system 200 may include one or more sensors (e.g., one or more sensors 237 of a die 205, one or more sensors 275 of one or more dies 240, or a combination thereof). In some implementations, a logic block 230, logic blocks 225, interface blocks 220, interface blocks 245, or a combination thereof may be configured to receive one or more indications based on measurements of one or more sensors of the system 200. For example, a logic block 230, logic blocks 225, interface blocks 220, or interface blocks 245 may be coupled with one or more sensors via one or more buses (not shown), or respective contacts (not shown). Such sensors may include temperature sensors, current sensors, voltage sensors, counters, and other types of sensors. In some examples, a logic block 230, one or more logic blocks 225, one or more interface blocks 220, one or more interface blocks 245, or a combination thereof may configure one or more operations based on output of the one or more sensors. For example, a logic block 230 may configure one or more operations of logic blocks 225 or interface blocks 220 based on signaling (e.g., indications, data) received from the one or more sensors. Additionally, or alternatively, a logic block 225 or an interface block 220 may generate access signaling for transmitting to a corresponding interface block 245 based on one or more sensors.

In some examples, circuitry of logic blocks 225, interface blocks 220, interface blocks 245, or a logic block 230, or any combination thereof may include components (e.g., transistors) formed at least in part from doped portions of a substrate of the respective die. In some examples, a substrate of a die 205 may have characteristics (e.g., materials, material characteristics, physical shapes or dimensions) that are different from those of a substrate of a die 240. Additionally, or alternatively, in some examples, transistors formed from a substrate of a die 205 may have characteristics (e.g., manufacturing characteristics, performance characteristics, physical shapes or dimensions) that are different from transistors formed from a substrate of a die 240 (e.g., in accordance with different transistor architectures, in accordance with different transistor designs).

In some examples, the interface blocks 220 may support a layout for one or more components within the interface blocks 220. For example, the layout may include pairing components to share an access port (e.g., a command port, a data port). Further, in some examples, the layout may support interfaces for a controller 215 (e.g., a host interface 216) that are different from interfaces for an interface block 245 (e.g., via the buses 221). For example, a host interface 216 may be synchronous and have separate channels for read and write operations, while an interface between an interface block 220 and one or more interface blocks 245 may be asynchronous and support both read and write operations with the same channel. In some examples, signaling of a host interface 216 may be implemented with a deterministic timing (e.g., deterministic between a controller 215 and a logic block 225 or one or more interface blocks 220), which may be associated with a configured timing between a first signal and a responsive second signal. In some examples, signaling between an interface block 220 and one or more interface blocks 245 may be implemented with a timing that is different from timing of a host interface 216 (e.g., in accordance with a different clock frequency, in accordance with a timing offset, such as a phase offset), which may be deterministic or non-deterministic.

A die 240 may include one or more units 265 (e.g., modules) that are separated from a semiconductor wafer having a pattern (e.g., a two-dimensional pattern) of units 265. Although each die 240 of the system 200 is illustrated with a single unit 265 (e.g., unit 265-a-1 of die 240-a-1, unit 265-a-2 of die 240-a-2), a die 240 in accordance with the described techniques may include any quantity of units 265, which may be arranged in various patterns (e.g., sets of one or more units 265 along a row direction, sets of one or more units 265 along a column direction, among other patterns). Each unit 265 may include at least the circuitry of a respective interface block 245, along with memory array(s) 250, a bus 251, a bus 246, and one or more contacts 247 corresponding to the respective interface block 245. In some examples, where applicable, each unit 265 may also include one or more buses 255, contacts 256, contacts 257, or contacts 260 (e.g., associated with a respective interface block 245 of a unit 265 of a different die 240), which may support various degrees of stackability or modularity among or via units 265 of other dies 240. Although examples of non-volatile storage 270 and sensors 275 are illustrated outside units 265, in some other examples, non-volatile storage 270, sensors 275, or both may additionally, or alternatively, be included in respective units 265.

In some examples, the interface blocks 220 may include circuitry configured to receive first access command signaling (e.g., from a host processor 210, from a controller 215, from a logic block 225, via a host interface 216, via one or more contacts 212 from a host processor 210 or controller 215 external to a die 205, based on a request from a host application), and to transmit second access command signaling to the respective (e.g., coupled) interface block 245 based on (e.g., in response to) the received first access command signaling. The interface blocks 245 may accordingly include circuitry configured to receive the second access command signaling from the respective interface block 220 and, in some examples, to access a respective set of one or more memory arrays 250 based on (e.g., in response to) the received second access command signaling. In various examples, the first access command signaling may include access commands that are associated with a type of operation (e.g., a read operation, a write operation, a refresh operation, a memory management operation), which may be associated with an indication of an address of the one or more memory arrays 250 (e.g., a logical address, a physical address). In some examples, the first access command signaling may include an indication of a logical address associated with the memory arrays 250, and circuitry of an interface block 220 may be configured to generate the second access command signaling to indicate a physical address associated with the memory arrays 250 (e.g., a row address, a column address, using a logical-to-physical (L2P) table or other mapping or calculation functionality of the interface block 220).

In some examples, to support write operations of the system 200, circuitry of the interface blocks 220 may be configured to receive (e.g., from a host processor 210, from a controller 215, from a logic block 225) first data signaling associated with the first access command signaling, and to transmit second data signaling (e.g., associated with second access command signaling) based on received first access command signaling and first data signaling. The interface blocks 245 may accordingly be configured to receive second data signaling, and to write data to one or more memory arrays 250 (e.g., in accordance with an indicated address associated with the first access command signaling) based on the received second access command signaling and second data signaling. In some examples, the interface blocks 220 may include an error control functionality (e.g., error detection circuitry, error correction circuitry, error correction code (ECC) logic, an ECC engine) that supports the interface blocks 220 generating the second data signaling based on performing an error control operation using the received first data signaling (e.g., detecting or correcting an error in the first data signaling, determining one or more parity bits to be conveyed in the second data signaling and written with the data).

In some examples, to support read operations of the system 200, circuitry of the interface blocks 245 may be configured to read data from the memory arrays 250 based on received second access command signaling, and to transmit first data signaling based on the read data. The interface blocks 220 may accordingly be configured to receive first data signaling, and to transmit second data signaling (e.g., to a host processor 210, to a controller 215, to a logic block 225) based on the received first data signaling. In some examples, the interface blocks 220 may include an error control functionality that supports the interface blocks 220 generating the second data signaling based on performing an error control operation using the received first data signaling (e.g., detecting or correcting an error in the first data signaling, which may include a calculation involving one or more parity bits received with the first data signaling).

In some examples, access command signaling that is transmitted to the interface blocks 245, among other signaling, may be generated (e.g., based on access command signaling received from a host processor 210, based on initiation signaling received from a host processor 210, without receiving or otherwise independent from signaling from a host processor 210) in accordance with various determination or generation techniques configured at the interface blocks 220 or the logic blocks 225 (e.g., based on a configuration for accessing memory arrays 250 that is modified at the interface blocks 220 or the logic blocks 225). In some examples, such techniques may involve signaling or other coordination with a logic block 230, a logic block 225, a host processor 210, one or more controllers 215, one or more instances of non-volatile storage, one or more sensors, or any combination thereof. Such techniques may support the interface blocks 220 or logic blocks 225 configuring aspects of the access operations performed on the memory arrays 250 by a respective interface block 245, among other operations. For example, interface blocks 220 or logic blocks 225 may include evaluation circuitry, access configuration circuitry, signaling circuitry, scheduling circuitry, repair circuitry, refresh circuitry, error control circuitry, adverse access (e.g., row hammer) mitigation circuitry, and other circuitry operable to configure operations associated with one or more dies (e.g., operations associated with accessing memory arrays 250 of the dies 240).

In some examples, functionality of a die 205 may be implemented as a semiconductor unit (e.g., a semiconductor system) that is formed with multiple semiconductor die portions (e.g., semiconductor chiplets, relatively smaller semiconductor dies), and each die portion may include respective portions of circuitry associated with the die 205. For example, a unit 280 may represent a portion of the circuitry components included in a die portion (e.g., in a chiplet), and the die portion may include an integer multiple of units 280. In some examples, each semiconductor die portion of a semiconductor unit may include different respective portions of circuitry. As a non-limiting example, a semiconductor unit (e.g., having the functionality of a die 205) may be formed by one or more first die portions having one or more units 280-a-1 and one or more second die portions having one or more units 280-a-2. The one or more units 280-a-1 may include one or more interface blocks 220, a logic block 225, or any combination thereof, and the one or more units 280-a-2 may include a host processor 210, one or more controllers 215, a logic block 230, or any combination thereof.

In accordance with examples as disclosed herein, one or more semiconductor components of a system 200 (e.g., a die 205, one or more dies 240), among other stacked semiconductor systems, may be formed with one or more dielectric portions through a substrate of the semiconductor component, through which a group of multiple vias may be formed to support signaling with circuitry of the semiconductor component. In a system 200, for example, each of one or more of such dielectric portions of a die 205 may include multiple vias that support contacts 212, contacts 222, or contacts 234, or a combination thereof. Additionally, or alternatively, each of one or more such dielectric portions of a die 205 may include multiple vias that support contacts 247, contacts 256, contacts 257, or contacts 260, or a combination thereof. In various examples, such vias may include the contacts themselves (e.g., for vias that extend to the surface of the semiconductor component), or may be otherwise coupled with (e.g., contiguous with, electrically coupled with, coupled via a redistribution layer) a contact portion that has a different cross-section than the vias. Such techniques may be implemented to support a relatively higher density of interconnections, interconnections with relatively larger cross sectional area, or interconnections with relatively lower capacitance or leakage, any one or more of which may increase signaling throughput or increase signaling speed (e.g., improving memory access speeds), or reduce power consumption (e.g., improving battery life, improving efficiency), among other benefits to performance of a system 200 or other stacked semiconductor system that implements contacts.

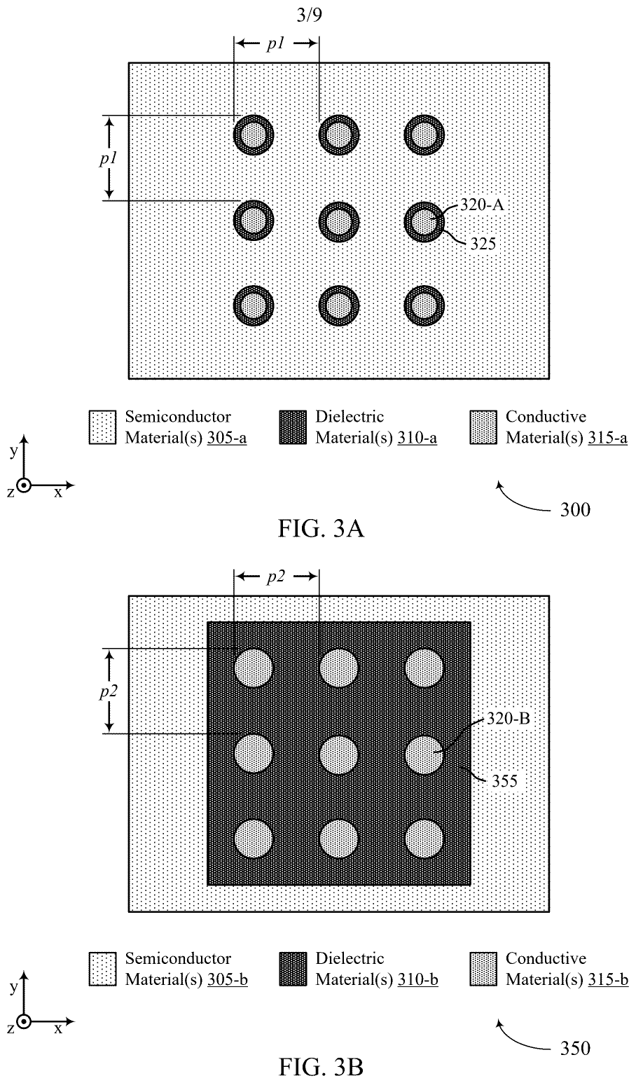

FIGS. 3A and 3B show examples of material layouts 300 and 350 that support vias through semiconductor substrates. Aspects of the material layouts 300 and 350 may be described with reference to an x-direction, a y-direction, and a z-direction of the illustrated coordinate systems, with FIGS. 3A and 3B providing cross-sectional views in an xy-plane (e.g., through a semiconductor substrate). In some implementations, the x-direction may be a direction over (e.g., parallel to, above, in-plane with) a substrate, the y-direction may be another direction over (e.g., parallel to, above, in-plane with) the substrate, and the z-direction may be a direction through or away from the substrate (e.g., perpendicular to or otherwise away from a surface of the substrate, a height direction, a thickness direction). The material layouts 300 and 350 illustrate examples of vias 320 that may be implemented in a semiconductor component (e.g., a wafer, a die, a chiplet).

Each of material layouts include one or more semiconductor materials 305, one or more dielectric materials 310, and one or more conductive materials 315. The semiconductor material(s) 305 may include various materials of a semiconductor substrate, such as a substrate of crystalline semiconductor (e.g., silicon, germanium, silicon-germanium, gallium arsenide, or gallium nitride), an SOI substrate (e.g., an SOG substrate, an SOS substrate), or epitaxial semiconductor materials formed on another substrate, among other examples or combinations thereof. In some examples, one or more portions of the semiconductor material(s) 305 may be doped to support circuitry, such as transistor circuitry (e.g., for doped semiconductor channels).

The conductive material(s) 315 may include one or more conductive materials (e.g., copper, tungsten, silver, or gold, among other materials or combinations or alloys thereof). The conductive material(s) 315 may be formed through the semiconductor material(s) 305 (e.g., at least in part along the z-direction) and, accordingly, may support through-substrate vias 320 (e.g., TSVs). In some examples, dielectric material(s) 310 may be formed between conductive materials material(s) 315 and semiconductor material(s) 305 to provide a material isolation (e.g., as a barrier material, to suppress material diffusion), an electrical isolation (e.g., as an electrically insulating material), or both.

FIG. 3A illustrates an example of vias 320-a that are each formed within a respective cavity through the semiconductor material(s) 305-a. For example, a pattern of cavities may be formed through the semiconductor material(s) 305-a in accordance with a pitch dimension p1, which may refer to a dimension between such cavities (e.g., a pitch dimension between vias 320-a). In various examples, the pitch dimension p1 may be limited to (e.g., bounded to a lower limit) based on a geometric accuracy of or between such cavities, based on a degree of taper (e.g., along the z-direction) of such cavities, based on a capability of reliably (e.g., uniformly) removing semiconductor material(s) 305-a, or based on a capability of reliably (e.g., uniformly, contiguously) forming materials (e.g., dielectric material(s) 310-a, conductive material(s) 315-a) within such cavities, among other limitations. In some examples, such limitations may also be associated with a thickness of the semiconductor material(s) 305-a, such as being based on an aspect ratio of dimensions in an xy-plane relative to a thickness along the z-direction. In the example of material layout 300, dielectric material(s) 310-a may be formed within each of such cavities to form dielectric liners 325. Conductive material(s) 315-a may subsequently be formed within each of the lined cavities (e.g., within dielectric liners 325) to form the vias 320-a.

In some implementations, the example of material layout 300 may be associated with a relatively limited density (e.g., along the x-direction, along the y-direction, in an xy-plane) of vias 320-a. For example, reductions to pitch dimension p1 beyond some limit may not be supported by geometric accuracy of some material removal techniques (e.g., associated photolithography limitations, associated with directional etching limitations), or may not be supported by capabilities of forming dielectric materials 310-a or conductive materials 315-b (e.g., without voids, discontinuities, or other irregularities that may impair performance), which may be related to an aspect ratio of such features. Further, some implementations of the material layout 300 may be associated with tradeoffs between cross-sectional area of vias 320-a, to support relatively high conductivity, and thickness of dielectric material(s) 310-a, to support relatively high electrical isolation, relatively low capacitance or leakage (e.g., between vias 320-a and semiconductor material(s) 305-a). For example, because each via 320-a is associated with a respective dielectric liner 325, the material layout 300 may be associated with a relatively high quantity of material interfaces that may limit density of vias 320-a.

FIG. 3B illustrates an example of vias 320-b that are each formed within a respective cavity through dielectric material(s) 310-b. For example, a relatively larger cavity may be formed through the semiconductor material(s) 305-b, within which dielectric material(s) 310-b may be deposited to form a dielectric portion 355 (e.g., a dielectric window). A pattern of cavities may then be formed through the dielectric portion 355 in accordance with a pitch dimension p2, which may refer to a dimension between such cavities (e.g., a pitch dimension between vias 320-b). In the example of material layout 350, conductive material(s) 315-b may be formed within each of such cavities in the dielectric portion 355 to form the vias 320-b.

In accordance with examples as disclosed herein, the example of material layout 350 may support a relatively greater density (e.g., along the x-direction, along the y-direction, in an xy-plane) of vias 320-b than the density of vias 320-a using the material layout 300. For example, the dielectric material(s) 310-b may support a relatively denser formation of cavities for vias 320-b, which may be associated with relatively favorable material removal characteristics of dielectric material(s) 310-b (e.g., more-uniform material removal, less tapered material removal) compared to semiconductor material(s) 305-a. Additionally, or alternatively, because conductive material(s) 315-b are formed directly in cavities formed in the dielectric portion 355, a cross sectional area of vias 320-b may be relatively greater than vias 320-a (e.g., for cases in which p2 is less than p1, for cases in which p2 is equal to p1), which may reduce resistance of the vias 320-b, or improve a uniformity of conductive material(s) 315-b (e.g., due to a lower aspect ratio of vias 320-b), or both. Further, because the dielectric material(s) 310-b of the dielectric portion 355 may be relatively thicker (e.g., along the x-direction, along the y-direction, or both between conductive material(s) 315-b and semiconductor material(s) 305-b), the conductive material(s) 315-b may have a higher degree of isolation from the semiconductor material(s) 305-b, which may support a relatively lower capacitance of or leakage associated with vias 320-b. Accordingly, vias 320-b may support relatively higher-speed signaling, or relatively lower power consumption, or both. Thus, the described techniques may implement sets of multiple vias 320-b in a dielectric portion 355 in a relatively dense manner (e.g., in accordance with a pitch dimension p2 of 1.25 μm or less) for high speed, high throughput, and efficient signaling between semiconductor components.

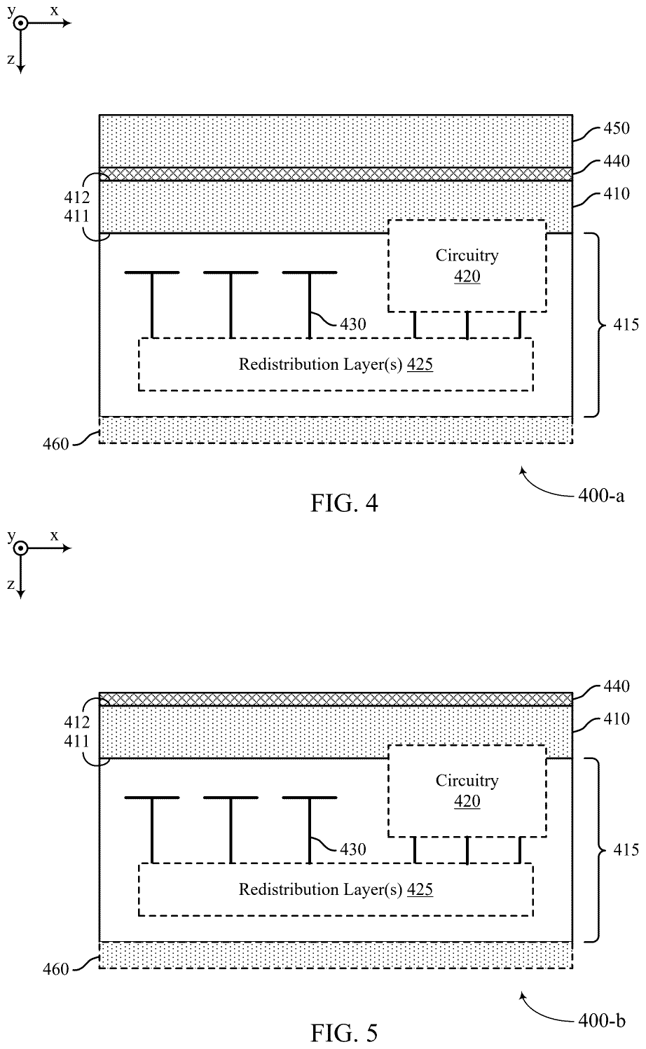

FIGS. 4 through 12 show examples of fabrication operations that support dielectric windows for groups of vias through semiconductor substrates in accordance with examples as disclosed herein. For example, FIGS. 4 through 12 may illustrate a sequence of operations for fabricating aspects of a semiconductor component 400 (e.g., a wafer, a die, a chiplet), which may be a portion of a system 100 (e.g., a host system 105, a memory system 110, or a combination thereof), or a system 200 (e.g., a die 205, a die 240) or another implementation of a semiconductor component (e.g., a memory component, a processing component). In some examples, the semiconductor component 400 may be a memory die, such as a DRAM die or a NAND die (e.g., a 3D-NAND die, a die having an arrangement of NAND memory cells arranged in a three-dimensional array), which may be configured to operate as a unitary semiconductor die (e.g., a standalone die, as a memory device 145), or may be configured for stacking with another die (e.g., as a die 205 or portion thereof, as a die 240).

Each of FIGS. 4 through 12 may illustrate aspects of the semiconductor component 400 after different subsets of the fabrication operations for forming the semiconductor component 400 (e.g., illustrated as a semiconductor component 400-a after a first set of one or more fabrication operations, as a semiconductor component 400-b after a second set of one or more fabrication operations, and so on). Each view of FIGS. 4 through 12 may be described with reference to an x-direction, a y-direction, and a z-direction of the illustrated coordinate system, which may correspond to the respective directions described with reference to the material layout 350. Aspects of the semiconductor component 400 may be illustrated in accordance with a cut plane (e.g., along an xz-plane) to show embedded features of the semiconductor component 400.

Operations illustrated in and described with reference to FIGS. 4 through 12 may be performed by a manufacturing system, such as a semiconductor fabrication system configured to perform additive operations (e.g., deposition, epitaxy, bonding), subtractive operations (e.g., etching, trenching, planarizing, polishing), modifying operations (e.g., oxidizing, doping, reacting, converting), and supporting operations (e.g., masking, patterning, photolithography, aligning), among other operations that support the described techniques for formation of the features of the semiconductor component 400. In some examples, operations performed by such a manufacturing system may be supported by a process controller or its components as described herein (e.g., including instructions stored in a non-transitory computer-readable medium that are executable by a processing system to cause the manufacturing system to perform the operations).

Although aspects of the semiconductor component illustrate examples of relative dimensions and quantities of various features, aspects of the semiconductor component 400 may be implemented with other relative dimensions or quantities of such features in accordance with examples as disclosed herein. Moreover, aspects of the semiconductor component 400 may be repeated in various manners (e.g., along the x-direction, along the y-direction, along the z-direction) to support two-dimensional array of vias 320, among other features. In the following description of the semiconductor component 400, some methods, techniques, processes, and operations may be performed in different orders, or at different times, or otherwise modified. Further, some operations for fabricating a semiconductor component 400 may be omitted from the described fabrication operations, or other operations may be added to the described fabrication operations.

FIG. 4 shows the semiconductor component 400 (e.g., as a semiconductor component 400-a) after a first set of one or more fabrication operations. For example, the first set of operations may include forming circuitry 420, conductors 430 (e.g., contacts), and one or more redistribution layers 425. The circuitry 420 may include transistor circuitry, which may include or be referred to as front end of line (FEOL) circuitry. For example, such circuitry may include doped portions of a substrate 410, which may include one or more semiconductor materials (e.g., semiconductor material(s) 305-b). The substrate 410 may support transistors or other components of the circuitry 420 (e.g., semiconductor channels of the circuitry 420). In some examples, circuitry 420 may include circuitry of a die 205 or a die 240, such as circuitry of one or more interface blocks, logic blocks, controllers, processors, storage, sensors, or other circuitry. In some examples, the circuitry 420 may include components of a memory array (e.g., one or more memory arrays 155, one or more memory arrays 250), such as a DRAM array, a NAND array, or another type of memory array.

In some examples, at least a portion of circuitry 420 may be formed on a surface 411 (e.g., a front side surface, a surface in an xy-plane) of the substrate 410, which may correspond to a side of the substrate 410 that is doped to form at least a portion of the circuitry 420. The substrate 410 may also include a surface 412 (e.g., a back side surface, a surface in an xy-plane) that is opposite the surface 411 (e.g., along the z-direction). In some examples, the surface 412 may correspond to a surface of the substrate 410 that is not doped. In some examples, at least a portion of the circuitry 420, the conductors 430, or the redistribution layer(s) 425 may include or be referred to as back end of line (BEOL) circuitry or middle end of line (MEOL) circuitry (e.g., interconnection circuitry, one or more conductive paths formed above transistor circuitry), and may include one or more materials of a portion 415 that is formed over the substrate 410. In some such examples, front-side operations to form circuitry 420, conductors 430, or redistribution layers 425 may be performed on a wafer (e.g., including at least a substrate 410 and a portion 415) before mounting the wafer to a carrier 460 (e.g., a sacrificial carrier, a sacrificial wafer) that supports performing back-side operations, including operations described herein. In some other examples, a carrier 460 may be omitted. In some examples, conductors 430 may be formed with at least a portion (e.g., a surface) that is coincident with the surface 411.

In some examples, the semiconductor component 400-a may also include a material 440, which may be implemented as an etch stop. For example, the material 440 may be a portion of silicon germanium (SiGe) or other semiconductor material that is implanted before front-side processing. In some such examples, the material 440 may be formed epitaxially from the substrate 410, or from another semiconductor portion 450 (e.g., sacrificial silicon), which may be the same material as the substrate 410. In some other examples, the material 440 may be a buried oxide etch stop formed from an SOI process.

In some examples, the conductors 430 may be formed concurrently with forming signal paths of the circuitry 420 (e.g., front side circuitry, as part of a front-side metallization operation. For example, conductors 430 may be formed from tungsten, and may include landing pads (e.g., along an xy-plane). By locating such landing pads relatively close to the surface 411, an aspect ratio of vias may be relatively reduced, which may improve processing of associated operations.

FIG. 5 shows the semiconductor component 400 (e.g., as a semiconductor component 400-b) after a second set of one or more fabrication operations. For example, where applicable (e.g., if a semiconductor portion 450 is included, if a material 440 is included), the second set of operations may include a semiconductor thinning (e.g., silicon thinning) operation that removes the semiconductor portion 450. In some implementations, the second set of operations may include a selective material removal operation that stops on the material 440. In various examples, the second set of operations may include a silicon back grind operation, a chemical mechanical planarization (CMP) operation, a silicon dry etch operation, or a silicon wet etch operation, or any combination thereof. In some examples, a combined thickness of the substrate 410 and the material 440 may be approximately 1.5 μm.

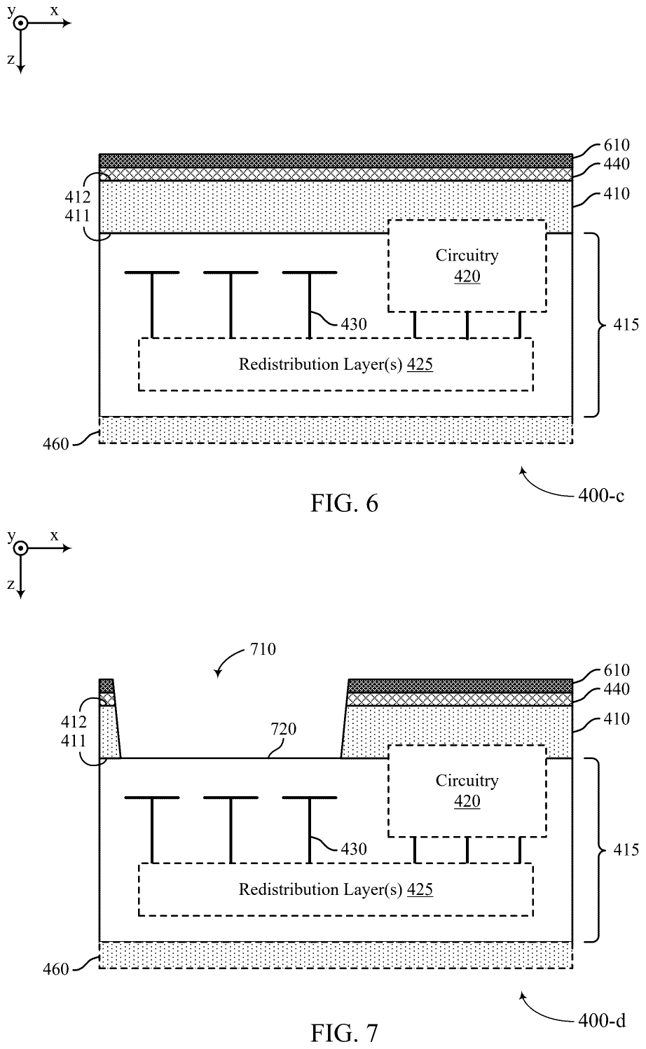

FIG. 6 shows the semiconductor component 400 (e.g., as a semiconductor component 400-c) after a third set of one or more fabrication operations. The third set of operations may include forming a material 610 over the material 440 (e.g., over a back side of the semiconductor component, over a back side of the material 440). In some examples, the material 610 may be selected to support a barrier functionality (e.g., as a barrier between copper or other material and the substrate 410), or a differential processing functionality (e.g., to support the material 610 being used as an etch stop. For example, the material 610 may be silicon carbon nitride (SiCN) which, in some examples, may be formed with a thickness of approximately 0.2 μm. In some other examples, the third set of operations (e.g., the material 610) may be omitted.

FIG. 7 shows the semiconductor component 400 (e.g., as a semiconductor component 400-d) after a fourth set of one or more fabrication operations. The fourth set of operations may include forming a cavity 710 through at least the substrate 410 and, where applicable, through the material 440 and the material 610. Forming the cavity 710 may illustrate a back side cavity formation (e.g., a backside trench operation), in which the cavity 710 is formed along the positive z-direction (e.g., from the same side as the surface 412, from a side of the substrate 410 that is opposite from the side of the substrate 410 that is doped to form at least a portion of the circuitry 420). In a backside trench operation, the cavity 710 may be tapered (e.g., having a decreasing cross section) along the positive z-direction. As illustrated, in some examples, forming the cavity 710 may be performed after forming the circuitry 420. Although the example of semiconductor component 400 is illustrated with a single cavity 710, a semiconductor component in accordance with the described techniques may be formed with any quantity of one or more cavities 710 at various positions (e.g., along the x-direction, along the y-direction, or both). In some examples, each cavity 710 may be aligned with conductors 430, which may include leveraging locations of the conductors 430 in an alignment operation (e.g., for registration of at least a portion of the fourth set of operations).

In some examples, forming the cavity 710 may expose a surface of a material 720 (e.g., of the portion 415) that is coincident with the surface 411. For example, the material 720 may be a dielectric material (e.g., silicon oxide) formed over the front side of the substrate 410 as part of a portion 415, which may provide an electrical isolation between components of the circuitry 420, the conductors 430, the redistribution layers 425, or any combination thereof.

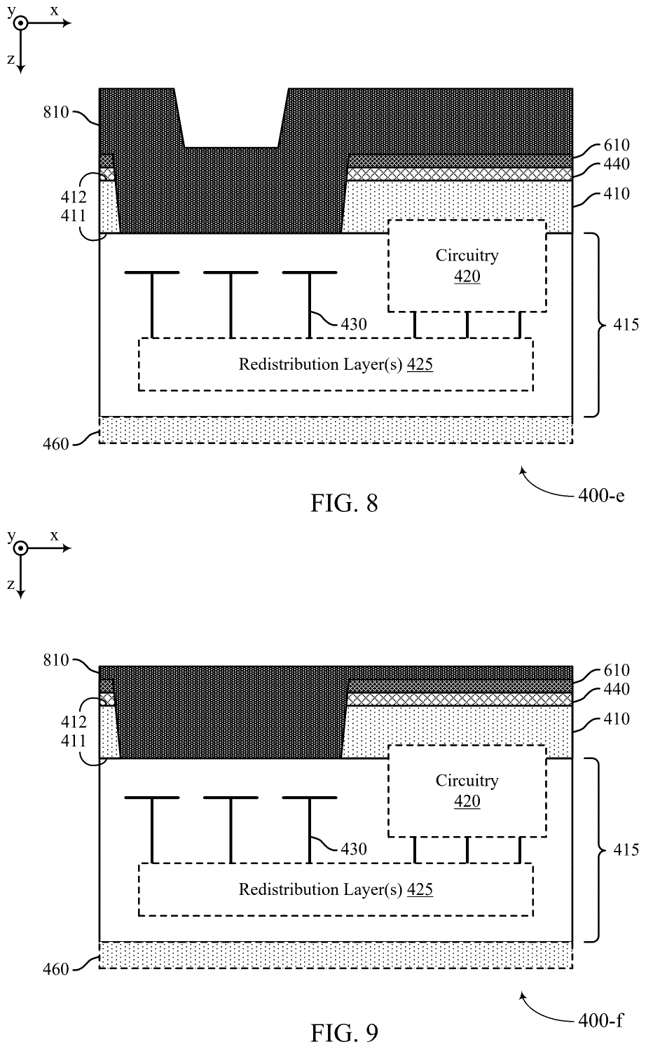

FIG. 8 shows the semiconductor component 400 (e.g., as a semiconductor component 400-e) after a fifth set of one or more fabrication operations. The fifth set of operations may be associated with forming a dielectric portion (e.g., a dielectric portion 355, one or more dielectric materials, in a trench gapfill operation) in at least in the cavity 710, which may include forming the dielectric portion through at least a depth of the substrate 410. In the example of semiconductor component 400-e, forming such a dielectric portion may include forming one or more dielectric materials 810, which may be an example of dielectric material(s) 310-b. The dielectric material(s) 810 may be formed over a surface of the semiconductor component 400 through which the cavity 710 is formed (e.g., a back side surface), which may be in contact with (e.g., cover) the exposed surface of the material 720, sidewalls of the substrate 410, the material 440, and the material 610, and cover an exposed surface (e.g., in an xy-plane) of the material 610. In some examples, the dielectric material(s) 810 may be or include silicon oxide, which may be the same as the material 720. However, in some examples, the dielectric material(s) 810 may be formed with a grain boundary or other observable boundary relative to the portion 415.

FIG. 9 shows the semiconductor component 400 (e.g., as a semiconductor component 400-f) after a sixth set of one or more fabrication operations. The sixth set of operations may include planarizing the dielectric material(s) 810 above the surface of the semiconductor component (e.g., in a dielectric CMP operation). In some examples, the dielectric material(s) 810 may be planarized such that a thickness over the material 610 is approximately 0.3 μm.

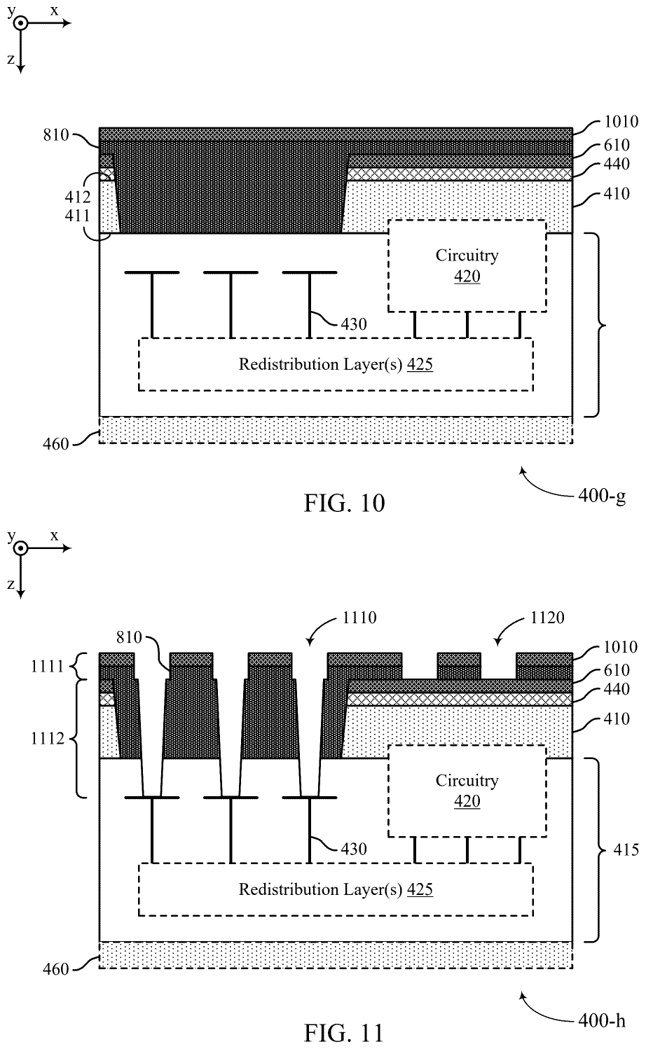

FIG. 10 shows the semiconductor component 400 (e.g., as a semiconductor component 400-g) after a seventh set of one or more fabrication operations. For example, the seventh set of operations may include forming a dielectric material 1010 over the planarized dielectric material(s) 810. In some examples, the dielectric material 1010 may be selected for high bonding (e.g., fusion) strength, among other characteristics. For example, the dielectric material 1010 may be an example of dielectric material 207 or dielectric material 242 that is selected for fusion bonding (e.g., hybrid bonding), such as between a die 205 and a die 240, or between dies 240, among other bonded semiconductor components. In some examples, the dielectric material 1010 may be or include silicon carbon nitride. In some examples, the seventh set of operations (e.g., the dielectric material 1010) may be omitted.

FIG. 11 shows the semiconductor component 400 (e.g., as a semiconductor component 400-h) after a eighth set of one or more fabrication operations. The eighth set of operations include forming a set of multiple cavities 1110 through at least the dielectric material(s) 810 and, where applicable, the dielectric material 1010 (e.g., through a relatively thin layer of the dielectric material 1010, through a relatively thick portion of the dielectric material(s) 810, without exposing sidewalls of the substrate 410, the material 440, or the material 610). Forming the cavities 1110 may illustrate a back side cavity formation, in which the cavities 1110 are formed along the positive z-direction. In a backside trench operation, the cavities 1110 may be tapered (e.g., having a decreasing cross section) along the positive z-direction. As illustrated, in some examples, forming the cavities 1110 may be performed after forming the circuitry 420. In some examples, forming the cavities 1110 may expose surfaces of the conductors 430 (e.g., a material of the conductors 430). For example, forming the cavities 1110 may implement a registration on the conductors 430, or may include a selective material removal operation that stops on a material of the conductors 430, or both. In some examples, the cavities 1110 may expose a portion of conductors 430 that correspond to a MEOL or BEOL layer.

In some examples, forming the cavities 1110 may implement two material removal operations associated with different cross-sections (e.g., in an xy-plane). For example, the cavities 1110 may be formed by forming first cavity portions through a depth 1111 (e.g., along the z-direction) and them forming second cavity portions through a depth 1112 (e.g., from the depth 1111). In some examples, the second cavity portions may have a respective cross-section that is narrower than the corresponding first cavity portion. In some examples, the first cavity portions may be associated with forming contact portions, and the second cavity portions may be associated with forming via portions. In some other examples, cavities 1110 may be formed with a single material removal operation associated with a single cross-section, which may taper along the z-direction.

In some examples, the eighth set of operations may also include forming cavities 1120, which may be associated with dummy contacts. In some examples, forming cavities 1120 include a selective material removal operation that stops on the material 610. In some examples, forming cavities 1120 may be formed concurrently with forming first cavity portions (e.g., through a depth 1111) of cavities 1110, and the material 610 may provide an etch stop for the cavities 1120 whereas the first cavity portions (e.g., the depth 1111) may be different, and may depend on processing characteristics such as time and temperature, among other characteristics. In some examples, contacts supported by the combination of cavities 1110 and cavities 1120 may be implemented across as much as 25% of the semiconductor component (e.g., in an xy-plane, for structural integrity), whereas cavities 1110 for vias 320-b (e.g., for communicative contacts) may be implemented across 2-3% of the semiconductor component.

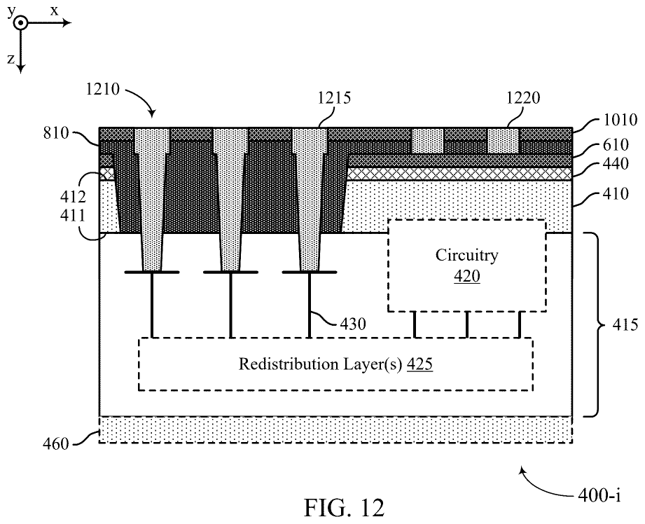

FIG. 12 shows the semiconductor component 400 (e.g., as a semiconductor component 400-i) after a ninth set of one or more fabrication operations. The ninth set of operations may include forming vias 1210 (e.g., nanovias, nano-TSVs) based on forming one or more conductive materials (e.g., conductive material(s) 315-b) in the cavities 1110, which may include forming such conductive material(s) in contact with a material of conductors 430. The vias 1210 may be an example of or include vias 320-b. In some examples, formation of the vias 1210 may include forming a conductive liner (e.g., an electrode material, such as tantalum or tantalum nitride) in contact with sidewalls of the cavities 1110, and filling the lined cavities 1110 with another conductive material (e.g., copper)

For examples in which the cavities 1110 are formed with first cavity portions (e.g., along a depth 1111) and second cavity portions (e.g., along a depth 1112), the conductive material(s) may be formed in the first cavity portions (e.g., via portions) and second cavity portions (e.g., bond pad portions) concurrently (e.g., in accordance with a dual damascene conductor formation, to concurrently form a via and a contact). In some such examples, the conductive material(s) may also be formed in cavities 1120 to form contacts 1220 (e.g., dummy contacts). In some other examples, forming vias 1210 may include one or more single damascene operations, such as when cavities 1110 are formed in accordance with a single cross-section (e.g., which may taper or may not taper), or when vias 1210 are formed with multiple iterations of forming and filling cavities.

In some examples, the semiconductor component 400 may be bonded with another component, such as another semiconductor component. For example, such bonding may include fusing the contacts 1215 with corresponding contacts 1215 of another semiconductor component 400 and, in some examples (e.g., where applicable), fusing contacts 1220 with corresponding contacts 1220 of another semiconductor component 400, among other bonding arrangements (e.g., bonding a contact 1215 of one semiconductor component 400 with a contact 1220 of another semiconductor component 400). In some examples, such bonding may also include bonding exposed portions of the dielectric material 1010 with corresponding exposed portions of the dielectric material 1010 of the other semiconductor component 400 (e.g., in accordance with a hybrid bonding arrangement). In some such examples, bonding may involve a hybrid bonding of two materials (e.g., a material of contacts 1215 and 1220, a dielectric material 1010), and, in some examples, not three materials (e.g., not a dielectric material 810, not a bonding of SiO).

Although forming the vias 1210 in the semiconductor component 400 may implement various back side operations (e.g., in accordance with a via-last operation), including those described with reference to the first through ninth set of operations, forming vias 320-b may additionally, or alternatively, implement one or more front side operations, or one or more back side operations, or various combinations thereof (e.g., in accordance with a via-middle operation, in accordance with a via-first operation). For example, a front side operation may be used to form a dielectric portion 355, which may be performed before, during, or after formation of circuitry 420, conductors 430, or redistribution layer(s) 425. In some such examples, the dielectric portion 355 may have cross section that tapers to a smaller dimension along the negative z-direction. Additionally, or alternatively, a front side operation may be used to form cavities for vias 320-b, or for filling such cavities, which may be performed before, during, or after formation of circuitry 420, conductors 430, or redistribution layer(s) 425. In some such examples, the vias 320-b may have cross section that tapers to a smaller dimension along the negative z-direction. In some such examples, conductors 430 may be formed in contact with previously-formed vias 320-b.

Thus, in accordance with these and other examples, multiple conductive vias 320-b may be formed through a dielectric portion 355. Such techniques may be implemented to support a relatively higher density of interconnections, interconnections with relatively larger cross sectional area, or interconnections with relatively lower capacitance or leakage, any one or more of which may increase signaling throughput or increase signaling speed (e.g., improving memory access speeds), or reduce power consumption (e.g., improving battery life, improving efficiency), among other benefits to performance of the semiconductor component 400 or other stacked semiconductor system that implements contacts. In some examples, such techniques may thus support the semiconductor component 400 being coupled (e.g., bonded) in a front-to-back or back-to-back coupling (e.g., stacking) of semiconductor components, or otherwise coupling with contacts 1215 on a back side of the semiconductor component 400.

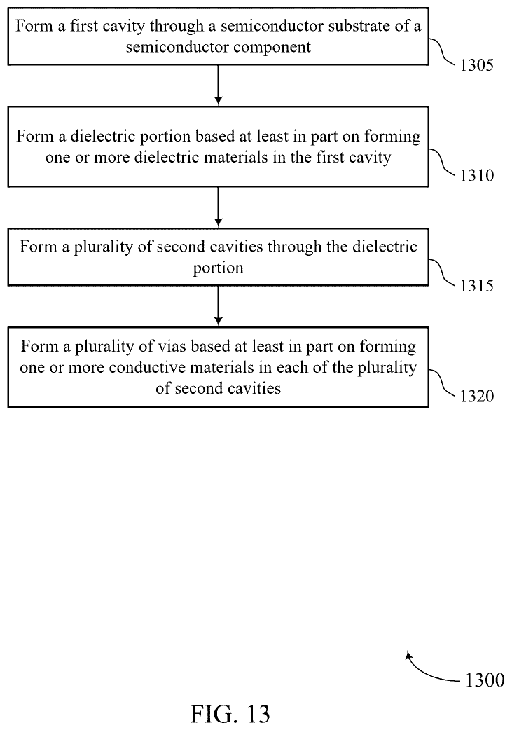

FIG. 13 shows a flowchart illustrating a method 1300 that supports dielectric windows for groups of vias through semiconductor substrates in accordance with examples as disclosed herein. The operations of method 1300 may be implemented by a manufacturing system or its components as described herein. For example, the operations of method 1300 may be performed by a manufacturing system as described with reference to FIGS. 3 through 12. In some examples, a manufacturing system may execute a set of instructions to control the functional elements of the device to perform the described functions. Additionally, or alternatively, the manufacturing system may perform aspects of the described functions using special-purpose hardware.

At 1305, the method may include forming a first cavity (e.g., a cavity 710) through a semiconductor substrate (e.g., a substrate 410) of a semiconductor component (e.g., a semiconductor component 400, a wafer, a die, a chiplet).

At 1310, the method may include forming a dielectric portion (e.g., a dielectric portion 355) based at least in part on forming one or more dielectric materials (e.g., dielectric material(s) 810) in the first cavity.

At 1315, the method may include forming a plurality of second cavities (e.g., cavities 1110) through the dielectric portion.

At 1320, the method may include forming a plurality of vias (e.g., vias 1210, vias 320-b) based at least in part on forming one or more conductive materials (e.g., conductive materials 315-b) in each of the plurality of second cavities.

In some examples, an apparatus (e.g., a manufacturing system) as described herein may perform a method or methods, such as the method 1300. The apparatus may include features, circuitry, logic, means, or instructions (e.g., a non-transitory computer-readable medium storing instructions executable by one or more controllers to control one or more functional elements of the manufacturing system), or any combination thereof for performing the following aspects of the present disclosure:

Aspect 1: A method, apparatus, or non-transitory computer-readable medium including operations, features, circuitry, logic, means, or instructions, or any combination thereof for forming a first cavity through a semiconductor substrate of a semiconductor component; forming a dielectric portion based at least in part on forming one or more dielectric materials in the first cavity; forming a plurality of second cavities through the dielectric portion; and forming a plurality of vias based at least in part on forming one or more conductive materials in each of the plurality of second cavities.

Aspect 2: The method, apparatus, or non-transitory computer-readable medium of aspect 1, where forming the dielectric portion includes operations, features, circuitry, logic, means, or instructions, or any combination thereof for forming the one or more dielectric materials (e.g., dielectric material(s) 810) over a surface of the semiconductor component through which the first cavity is formed and planarizing the one or more dielectric materials above the surface of the semiconductor component after forming the one or more dielectric materials over the surface of the semiconductor component.

Aspect 3: The method, apparatus, or non-transitory computer-readable medium of aspect 2, further including operations, features, circuitry, logic, means, or instructions, or any combination thereof for forming a second dielectric material (e.g., a dielectric material 1010) over the planarized one or more dielectric materials, where the plurality of second cavities are formed through the second dielectric material and through the dielectric portion formed through the semiconductor substrate.

Aspect 4: The method, apparatus, or non-transitory computer-readable medium of aspect 3, where the second dielectric material includes silicon carbon nitride.

Aspect 5: The method, apparatus, or non-transitory computer-readable medium of any of aspects 3 through 4, where forming the plurality of second cavities includes operations, features, circuitry, logic, means, or instructions, or any combination thereof for forming a plurality of first cavity portions through the second dielectric material and through a depth (e.g., at least a portion of a depth 1111) of the dielectric portion and forming, a plurality of second cavity portions each corresponding to one of the plurality of second cavity portions, each of the plurality of second cavity portions formed from the depth and through the dielectric portion (e.g., through a depth 1112), and each of the plurality of second cavity portions having a respective cross-section that is narrower than the corresponding first cavity portion.

Aspect 6: The method, apparatus, or non-transitory computer-readable medium of aspect 5, where forming the plurality of vias includes operations, features, circuitry, logic, means, or instructions, or any combination thereof for forming, at least one of the one or more conductive materials, in the plurality of first cavity portions and the plurality of second cavity portions concurrently (e.g., in accordance with a dual-damascene conductor formation).

Aspect 7: The method, apparatus, or non-transitory computer-readable medium of any of aspects 3 through 6, further including operations, features, circuitry, logic, means, or instructions, or any combination thereof for bonding the semiconductor component with a second semiconductor component, where the bonding includes fusing at least one of the one or more conductive materials of the plurality of vias with corresponding portions of the at least one of the one or more conductive materials of the second semiconductor component and fusing the second dielectric material with a corresponding portion of the second dielectric material of the second semiconductor component.

Aspect 8: The method, apparatus, or non-transitory computer-readable medium of any of aspects 1 through 7, where forming the first cavity includes operations, features, circuitry, logic, means, or instructions, or any combination thereof for forming the first cavity from a second side of the semiconductor substrate (e.g., a back side), the second side of the semiconductor substrate opposite a first side of the semiconductor substrate that is doped to form transistor circuitry of the semiconductor component.

Aspect 9: The method, apparatus, or non-transitory computer-readable medium of aspect 8, where forming the first cavity exposes a material that is coincident with the first side of the semiconductor substrate (e.g., a dielectric material of a portion 415) and forming the dielectric portion includes forming at least one of the one or more dielectric materials in contact with the material that is coincident with the first side of the semiconductor substrate.

Aspect 10: The method, apparatus, or non-transitory computer-readable medium of any of aspects 8 through 9, where forming the first cavity is performed after forming the transistor circuitry of the semiconductor component.

Aspect 11: The method, apparatus, or non-transitory computer-readable medium of any of aspects 1 through 10, where forming the plurality of second cavities includes operations, features, circuitry, logic, means, or instructions, or any combination thereof for forming the plurality of second cavities from a second side of the semiconductor substrate (e.g., a back side) that is opposite a first side of the semiconductor substrate that is doped to form transistor circuitry of the semiconductor component.

Aspect 12: The method, apparatus, or non-transitory computer-readable medium of aspect 11, where forming the plurality of second cavities exposes respective portions of a second conductive material (e.g., material of conductors 430) that is coupled with the transistor circuitry of the semiconductor component and forming the plurality of vias includes forming at least one of the one or more conductive materials in contact with the respective portions of the second conductive material.

Aspect 13: The method, apparatus, or non-transitory computer-readable medium of aspect 12, where the second conductive material includes tungsten.

Aspect 14: The method, apparatus, or non-transitory computer-readable medium of any of aspects 1 through 13, where the one or more dielectric materials include silicon oxide.

Aspect 15: The method, apparatus, or non-transitory computer-readable medium of any of aspects 1 through 14, where forming the one or more conductive materials includes operations, features, circuitry, logic, means, or instructions, or any combination thereof for forming an electrode liner (e.g., tantalum, tantalum nitride) along surfaces of the plurality of second cavities and forming copper in contact with the electrode liner after forming the electrode liner.

Aspect 16: The method, apparatus, or non-transitory computer-readable medium of any of aspects 1 through 15, where the semiconductor substrate includes a crystalline semiconductor material.

It should be noted that the aspects described herein describe possible implementations, and that the operations and the steps may be rearranged or otherwise modified and that other implementations are possible. Further, portions from two or more of the methods may be combined.

An apparatus is described. The following provides an overview of aspects of the apparatus as described herein:

Aspect 17: A semiconductor component, including: a semiconductor substrate; circuitry formed at least in part from a doped portion of the semiconductor substrate; a dielectric portion including one or more dielectric materials formed through the semiconductor substrate; and a plurality of vias each including one or more conductive materials formed through the dielectric portion, where at least one of the plurality of vias is coupled with the circuitry formed at least in part from the doped portion of the semiconductor substrate.

Aspect 18: The semiconductor component of aspect 17, further including: a second dielectric material over the dielectric portion, where the plurality of vias each include the one or more conductive materials formed through the second dielectric material.

Aspect 19: The semiconductor component of aspect 18, where the second dielectric material includes silicon carbon nitride.

Aspect 20: The semiconductor component of any of aspects 17 through 19, where each of the plurality of vias includes: a first via portion intersecting a surface of the semiconductor component; and a second via portion extending from the first via portion and through the semiconductor substrate, the second via portion having a cross-section that is smaller than the first via portion.

Aspect 21: The semiconductor component of aspect 20, where, for each of the plurality of vias, at least one of the one or more conductive materials is contiguously formed between the first via portion and the second via portion (e.g., in accordance with a dual-damascene conductor formation).

Aspect 22: The semiconductor component of any of aspects 17 through 21, where the dielectric portion tapers from a first cross-section at a first side of the semiconductor substrate that is doped to form the doped portion to a second cross-section at a second side of the semiconductor substrate opposite the first side, the second cross-section being wider than the first cross-section.

Aspect 23: The semiconductor component of aspect 22, where the dielectric portion is in contact with a material that is coincident with the first side of the semiconductor substrate.

Aspect 24: The semiconductor component of any of aspects 17 through 23, where each of the plurality of vias is formed in contact with a second conductive material that is different than the one or more conductive materials.

Aspect 25: The semiconductor component of any of aspects 17 through 24, where the one or more dielectric materials include silicon oxide.

Aspect 26: The semiconductor component of any of aspects 17 through 25, where the semiconductor substrate includes a crystalline semiconductor material.

An apparatus is described. The following provides an overview of aspects of the apparatus as described herein:

Aspect 27: A semiconductor component formed by a process, including: forming a first cavity through a semiconductor substrate of the semiconductor component; forming a dielectric portion based at least in part on forming one or more dielectric materials in the first cavity; forming a plurality of second cavities through the dielectric portion; and forming a plurality of vias based at least in part on forming one or more conductive materials in each of the plurality of second cavities.

An apparatus is described. The following provides an overview of aspects of the apparatus as described herein:

Aspect 28: A semiconductor system, including: a first semiconductor component, including: a semiconductor substrate; first circuitry formed at least in part from a doped portion of the semiconductor substrate; a dielectric portion including one or more dielectric materials formed through the semiconductor substrate; and a plurality of first vias each including one or more conductive materials formed through the dielectric portion; and a second semiconductor component bonded with the first semiconductor component, the second semiconductor component, including: a plurality of second vias; and second circuitry coupled with the first circuitry based at least in part on a fusion between surfaces of the plurality of second vias and surfaces of the plurality of first vias.

Aspect 29: The semiconductor system of aspect 28, where: the first circuitry includes a first portion of a processing system of the semiconductor system; and the second circuitry includes a second portion of the processing system of the semiconductor system.

An apparatus is described. The following provides an overview of aspects of the apparatus as described herein:

Aspect 30: A semiconductor system, including: a first semiconductor component, including: a semiconductor substrate; a memory array; first circuitry operable for accessing the memory array; a dielectric portion including one or more dielectric materials formed through the semiconductor substrate; and a plurality of vias coupled with the first circuitry and each including one or more conductive materials formed through the dielectric portion; and a second semiconductor component bonded with the first semiconductor component, the second semiconductor component, including: a plurality of contacts at a surface of the second semiconductor component; and second circuitry operable for accessing the memory array, the second circuitry coupled with the first circuitry based at least in part on a fusion between the plurality of contacts and surfaces of the plurality of vias.

Aspect 31: The semiconductor system of aspect 30, where the memory array comprises DRAM memory cells or NAND memory cells (e.g., a 3D NAND array).

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (e.g., in conductive contact with, connected with, coupled with) one another if there is any electrical path (e.g., conductive path) between the components that can, at any time, support the flow of signals (e.g., charge, current, voltage) between the components. A conductive path between components that are in electronic communication with each other (e.g., in conductive contact with, connected with, coupled with) may be an open circuit or a closed circuit based on the operation of the device that includes the connected components. A conductive path between connected components may be a direct conductive path between the components or may be an indirect conductive path that includes intermediate components, such as switches, transistors, or other components. In some examples, the flow of signals between the connected components may be interrupted for a time, for example, using one or more intermediate components such as switches or transistors.

The term “isolated” may refer to a relationship between components in which signals are not presently capable of flowing between the components. Components are isolated from each other if there is an open circuit between them. For example, two components separated by a switch that is positioned between the components are isolated from each other when the switch is open. When a component isolates two components, the component may initiate a change that prevents signals from flowing between the other components using a conductive path that previously permitted signals to flow.

The term “coupling” (e.g., “electrically coupling”) may refer to condition of moving from an open-circuit relationship between components in which signals are not presently capable of being communicated between the components (e.g., over a conductive path) to a closed-circuit relationship between components in which signals are capable of being communicated between components (e.g., over the conductive path). When a component, such as a controller, couples other components together, the component may initiate a change that allows signals to flow between the other components over a conductive path that previously did not permit signals to flow.

The terms “layer” and “level” may refer to an organization (e.g., a stratum, a sheet) of a geometrical structure (e.g., relative to a substrate). Each layer or level may have three dimensions (e.g., height, width, and depth) and may cover at least a portion of a surface. For example, a layer or level may be a three dimensional structure where two dimensions are greater than a third, e.g., a thin-film. Layers or levels may include different elements, components, or materials. In some examples, one layer or level may be composed of two or more sublayers or sublevels.

The description set forth herein, in connection with the appended drawings, describes example configurations and does not represent all the examples that may be implemented or that are within the scope of the claims. The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Similar components may be distinguished by following the reference label by one or more dashes and additional labeling that distinguishes among the similar components. If just the first reference label is used in the specification, the description is applicable to any one of the similar components having the same first reference label irrespective of the additional reference labels.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or a processor.

The descriptions and drawings are provided to enable a person having ordinary skill in the art to make or use the disclosure. Various modifications to the disclosure will be apparent to the person having ordinary skill in the art, and the techniques disclosed herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A method for semiconductor manufacture, comprising:
forming a first cavity through a semiconductor substrate of a semiconductor component;
forming a dielectric portion based at least in part on forming one or more dielectric materials in the first cavity;
forming a plurality of second cavities through the dielectric portion; and
forming a plurality of vias based at least in part on forming one or more conductive materials in each of the plurality of second cavities.

2. The method of claim 1, wherein forming the dielectric portion comprises:
forming the one or more dielectric materials over a surface of the semiconductor component through which the first cavity is formed; and
planarizing the one or more dielectric materials above the surface of the semiconductor component after forming the one or more dielectric materials over the surface of the semiconductor component.

3. The method of claim 2, further comprising:
forming a second dielectric material over the planarized one or more dielectric materials, wherein the plurality of second cavities are formed through the second dielectric material and through the dielectric portion formed through the semiconductor substrate.

4. The method of claim 3, wherein the second dielectric material comprises silicon carbon nitride.

5. The method of claim 3, wherein forming the plurality of second cavities comprises:
forming a plurality of first cavity portions through the second dielectric material and through a depth of the dielectric portion; and
forming, a plurality of second cavity portions each corresponding to one of the plurality of second cavity portions, each of the plurality of second cavity portions formed from the depth and through the dielectric portion, and each of the plurality of second cavity portions having a respective cross-section that is narrower than the corresponding first cavity portion.

6. The method of claim 5, wherein forming the plurality of vias comprises:
forming, at least one of the one or more conductive materials, in the plurality of first cavity portions and the plurality of second cavity portions concurrently.

7. The method of claim 3, further comprising:
bonding the semiconductor component with a second semiconductor component, wherein the bonding comprises:
fusing at least one of the one or more conductive materials of the plurality of vias with corresponding portions of the at least one of the one or more conductive materials of the second semiconductor component; and
fusing the second dielectric material with a corresponding portion of the second dielectric material of the second semiconductor component.

8. The method of claim 1, wherein forming the first cavity comprises:
forming the first cavity from a second side of the semiconductor substrate, the second side of the semiconductor substrate opposite a first side of the semiconductor substrate that is doped to form transistor circuitry of the semiconductor component.

9. The method of claim 8, wherein:
forming the first cavity exposes a material that is coincident with the first side of the semiconductor substrate; and
forming the dielectric portion comprises forming at least one of the one or more dielectric materials in contact with the material that is coincident with the first side of the semiconductor substrate.

10. The method of claim 8, wherein forming the first cavity is performed after forming the transistor circuitry of the semiconductor component.

11. The method of claim 1, wherein forming the plurality of second cavities comprises:
forming the plurality of second cavities from a second side of the semiconductor substrate that is opposite a first side of the semiconductor substrate that is doped to form transistor circuitry of the semiconductor component.

12. The method of claim 11, wherein:
forming the plurality of second cavities exposes respective portions of a second conductive material that is coupled with the transistor circuitry of the semiconductor component; and
forming the plurality of vias comprises forming at least one of the one or more conductive materials in contact with the respective portions of the second conductive material.

13. The method of claim 12, wherein the second conductive material comprises tungsten.

14. The method of claim 1, wherein the one or more dielectric materials comprise silicon oxide.

15. The method of claim 1, wherein forming the one or more conductive materials comprises:
forming an electrode liner along surfaces of the plurality of second cavities; and
forming copper in contact with the electrode liner after forming the electrode liner.

16. The method of claim 1, wherein the semiconductor substrate comprises a crystalline semiconductor material.

17. A semiconductor component, comprising:
a semiconductor substrate;
circuitry formed at least in part from a doped portion of the semiconductor substrate;
a dielectric portion comprising one or more dielectric materials formed through the semiconductor substrate; and
a plurality of vias each comprising one or more conductive materials formed through the dielectric portion, wherein at least one of the plurality of vias is coupled with the circuitry formed at least in part from the doped portion of the semiconductor substrate.

18. The semiconductor component of claim 17, further comprising:
a second dielectric material over the dielectric portion, wherein the plurality of vias each comprise the one or more conductive materials formed through the second dielectric material.

19. The semiconductor component of claim 18, wherein the second dielectric material comprises silicon carbon nitride.

20. The semiconductor component of claim 17, wherein each of the plurality of vias comprises:
a first via portion intersecting a surface of the semiconductor component; and
a second via portion extending from the first via portion and through the semiconductor substrate, the second via portion having a cross-section that is smaller than the first via portion.

21. The semiconductor component of claim 20, wherein, for each of the plurality of vias, at least one of the one or more conductive materials is contiguously formed between the first via portion and the second via portion.

22. The semiconductor component of claim 17, wherein the dielectric portion tapers from a first cross-section at a first side of the semiconductor substrate that is doped to form the doped portion to a second cross-section at a second side of the semiconductor substrate opposite the first side, the second cross-section being wider than the first cross-section.

23. The semiconductor component of claim 22, wherein the dielectric portion is in contact with a material that is coincident with the first side of the semiconductor substrate.

24. The semiconductor component of claim 17, wherein each of the plurality of vias is formed in contact with a second conductive material that is different than the one or more conductive materials.

25. The semiconductor component of claim 17, wherein the one or more dielectric materials comprise silicon oxide.

26. The semiconductor component of claim 17, wherein the semiconductor substrate comprises a crystalline semiconductor material.

27. A semiconductor component formed by a process, comprising:
forming a first cavity through a semiconductor substrate of the semiconductor component;
forming a dielectric portion based at least in part on forming one or more dielectric materials in the first cavity;
forming a plurality of second cavities through the dielectric portion; and
forming a plurality of vias based at least in part on forming one or more conductive materials in each of the plurality of second cavities.

28. A semiconductor system, comprising:
a first semiconductor component, comprising:
a semiconductor substrate;
first circuitry formed at least in part from a doped portion of the semiconductor substrate;
a dielectric portion comprising one or more dielectric materials formed through the semiconductor substrate; and
a plurality of first vias each comprising one or more conductive materials formed through the dielectric portion; and
a second semiconductor component bonded with the first semiconductor component, the second semiconductor component, comprising:
a plurality of second vias; and
second circuitry coupled with the first circuitry based at least in part on a fusion between surfaces of the plurality of second vias and surfaces of the plurality of first vias.

29. The semiconductor system of claim 28, wherein:
the first circuitry comprises a first portion of a processing system of the semiconductor system; and
the second circuitry comprises a second portion of the processing system of the semiconductor system.

30. A semiconductor system, comprising:
a first semiconductor component, comprising:
a semiconductor substrate;
a memory array;
first circuitry operable for accessing the memory array;
a dielectric portion comprising one or more dielectric materials formed through the semiconductor substrate; and
a plurality of vias coupled with the first circuitry and each comprising one or more conductive materials formed through the dielectric portion; and
a second semiconductor component bonded with the first semiconductor component, the second semiconductor component, comprising:
a plurality of contacts at a surface of the second semiconductor component; and
second circuitry operable for accessing the memory array, the second circuitry coupled with the first circuitry based at least in part on a fusion between the plurality of contacts and surfaces of the plurality of vias.

31. The semiconductor system of claim 30, wherein the memory array comprises dynamic random access memory (DRAM) memory cells or NAND memory cells.
